(19) United States
(12) Patent Application Publication
(10) Pub. No.: US 2024/0395648 A1
(43) Pub. Date: Nov. 28, 2024

(54) SEMICONDUCTOR DEVICE

(71) Applicant: ROHM CO., LTD., Kyoto-shi (JP)

(72) Inventor: Kazuki YOSHIDA, Kyoto-shi (JP)

(73) Assignee: ROHM CO., LTD., Kyoto-shi (JP)

(21) Appl. No.: 18/795,268

(22) Filed: Aug. 6, 2024

Related U.S. Application Data
(63) Continuation of application No. PCT/JP2023/002870, filed on Jan. 30, 2023.

(30) Foreign Application Priority Data
Feb. 16, 2022 (JP) 2022-022309

(51) Int. Cl. H01L 23/31; H01L 23/00; H01L 23/29; H01L 23/495

(52) U.S. Cl. CPC H01L 23/3157; H01L 23/291; H01L 23/293; H01L 23/3107; H01L 24/05; H01L 24/06; H01L 23/49562; H01L 24/32; H01L 24/48; H01L 24/73; H01L 2224/05639; H01L 2224/0603; H01L 2224/06051; H01L 2224/06181; H01L 2224/32245; H01L 2224/48245; H01L 2224/73265

(57) ABSTRACT

A semiconductor device includes: a semiconductor layer; first and second wiring lines; an insulating layer that has a first opening and a second opening from which a part of the first wiring line and a part of the second wiring line are exposed, respectively; and first and second electrodes. The first electrode extends over the first wiring line and the insulating layer, and has a first edge on the insulating layer. The second electrode extends over the second wiring line and the insulating layer, and has a second edge on the insulating layer. The insulating layer includes an interposed portion interposed between the first edge and the second edge, which face each other. The interposed portion includes a groove that is recessed from the upper surface of the interposed portion toward the semiconductor layer. The groove extends along at least one of the first edge and the second edge.

### CROSS-REFERENCE TO RELATED APPLICATIONS

The present application is a continuation application of PCT Application No. PCT/JP2023/002870, filed on Jan. 30, 2023, which corresponds to Japanese Patent Application No. 2022-022309 filed on Feb. 16, 2022, with the Japan Patent Office, and the entire disclosures of these applications are incorporated herein by reference.

### BACKGROUND

The present disclosure relates to a semiconductor device.

A semiconductor device is known that includes a semiconductor layer, an insulating film formed on the upper surface of the semiconductor layer, and a first electrode and a second electrode formed to be spaced apart from each other on the insulating film (see Japanese Laid-Open Patent Publication No. 2020-194881). In this semiconductor device, the voltage applied to the first electrode differs from the voltage applied to the second electrode.

### BRIEF DESCRIPTION OF DRAWINGS

FIG. 1 is a plan view showing a schematic planar structure of a semiconductor device according to a first embodiment.

FIG. 2 is an enlarged view of a MOSFET of the semiconductor device of FIG. 1.

FIG. 3 is a cross-sectional view showing a schematic cross-sectional structure taken along line F3-F3 in FIG. 2.

FIG. 4 is an enlarged view of the gate electrode and its surrounding area in FIG. 2.

FIG. 5 is a plan view showing a schematic planar structure of a MOSFET in a semiconductor device according to a second embodiment.

FIG. 6 is a cross-sectional view showing a schematic cross-sectional structure taken along line F6-F6 in FIG. 5.

FIG. 7 is a plan view showing a schematic planar structure of a part of a semiconductor device according to a modification.

FIG. 8 is an enlarged plan view of a gate electrode and its surrounding area in a semiconductor device according to a modification.

FIG. 9 is an enlarged plan view of a gate electrode and its surrounding area in a semiconductor device according to a modification.

FIG. 10 is an enlarged plan view of a gate electrode and its surrounding area in a semiconductor device according to a modification.

FIG. 11 is an enlarged plan view of a gate electrode and its surrounding area in a semiconductor device according to a modification.

FIG. 12 is an enlarged plan view of a gate electrode and its surrounding area in a semiconductor device according to a modification.

### DETAILED DESCRIPTION

Embodiments of a semiconductor device according to the present disclosure will be described below with reference to the drawings. In the drawings, components may not be drawn to scale for simplicity and clarity of illustration. In a cross-sectional view, hatching may be omitted to facilitate understanding. The accompanying drawings illustrate exemplary embodiments in accordance with the present disclosure and are not intended to limit the present disclosure.

This detailed description provides a comprehensive understanding of the methods, apparatuses, and/or systems described. Exemplary embodiments may have different forms, and are not limited to the examples described.

### First Embodiment

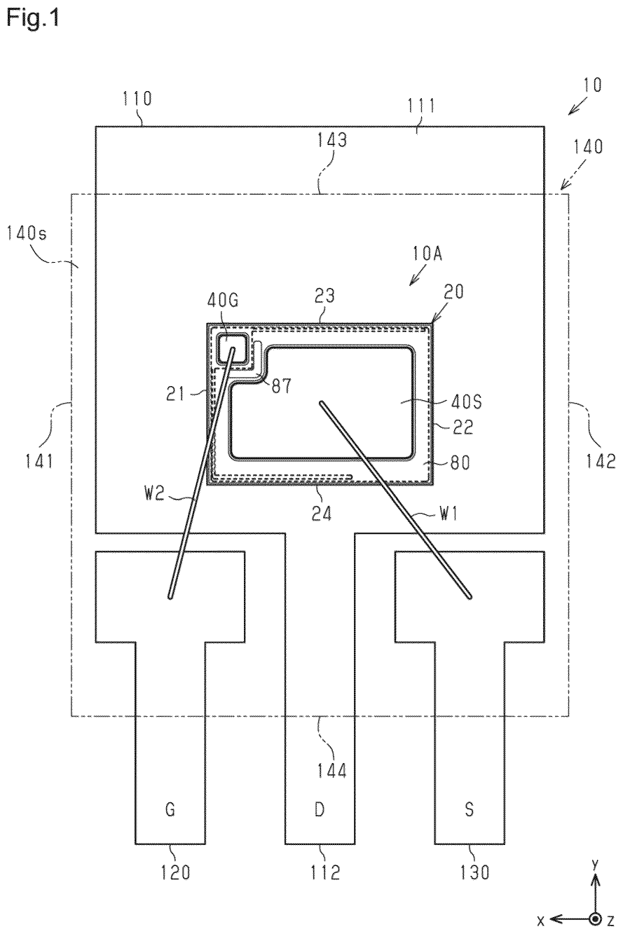

Referring to FIGS. 1 to 4, the configuration of a semiconductor device 10 of a first embodiment is now described.

FIG. 1 is a schematic plan view of the semiconductor device 10. In FIG. 1, for illustrative purposes, a sealing plastic 140, which will be described below, is indicated by a long-dash double-short-dash line, and the internal structure of the semiconductor device 10 is indicated by solid lines.

As shown in FIG. 1, the semiconductor device 10 includes a metal-oxide-semiconductor field-effect transistor (MOSFET) 10A, a first frame 110 on which the MOSFET 10A is mounted, a second frame 120 and a third frame 130 electrically connected to the MOSFET 10A, and the sealing plastic 140 that seals the MOSFET 10A and the frames 110, 120, and 130.

The sealing plastic 140 has the shape of a rectangular flat plate. The sealing plastic 140 includes a plastic front surface 140s, a plastic back surface (not shown) opposite the plastic front surface 140s, and first to fourth plastic side surfaces 141 to 144 intersecting with both the plastic front surface 140s and the plastic back surface. In this embodiment, the first to fourth plastic side surfaces 141 to 144 are perpendicular to both the plastic front surface 140s and the plastic back surface.

The thickness direction of the sealing plastic 140 is defined as a z-direction, and two directions perpendicular to the z-direction are defined as an x-direction and a y-direction. As viewed from the z-direction, the first and second plastic side surfaces 141 and 142 form opposite end surfaces in the x-direction, and the third and fourth plastic side surfaces 143 and 144 form opposite end surfaces in the y-direction. As viewed from the z-direction, the first and second plastic side surfaces 141 and 142 extend in the y-direction, and the third and fourth plastic side surfaces 143 and 144 extend in the x-direction.

The frames 110, 120, and 130 are made of a material including at least one of copper (Cu) or aluminum (Al), for example.

The first frame 110 includes a first die pad portion 111, on which the MOSFET 10A is mounted, and a first lead portion 112, which extends from the first die pad portion 111. In this embodiment, the first die pad portion 111 and the first lead portion 112 are integral. The first die pad portion 111 protrudes from the third plastic side surface 143. The first lead portion 112 protrudes from the fourth plastic side surface 144.

Both the second frame 120 and the third frame 130 are located closer to the fourth plastic side surface 144 than the first die pad portion 111. The second frame 120 is located closer to the first plastic side surface 141 than the first lead portion 112. The third frame 130 is located closer to the second plastic side surface 142 than the first lead portion 112. Both the second frame 120 and the third frame 130 protrude from the fourth plastic side surface 144.

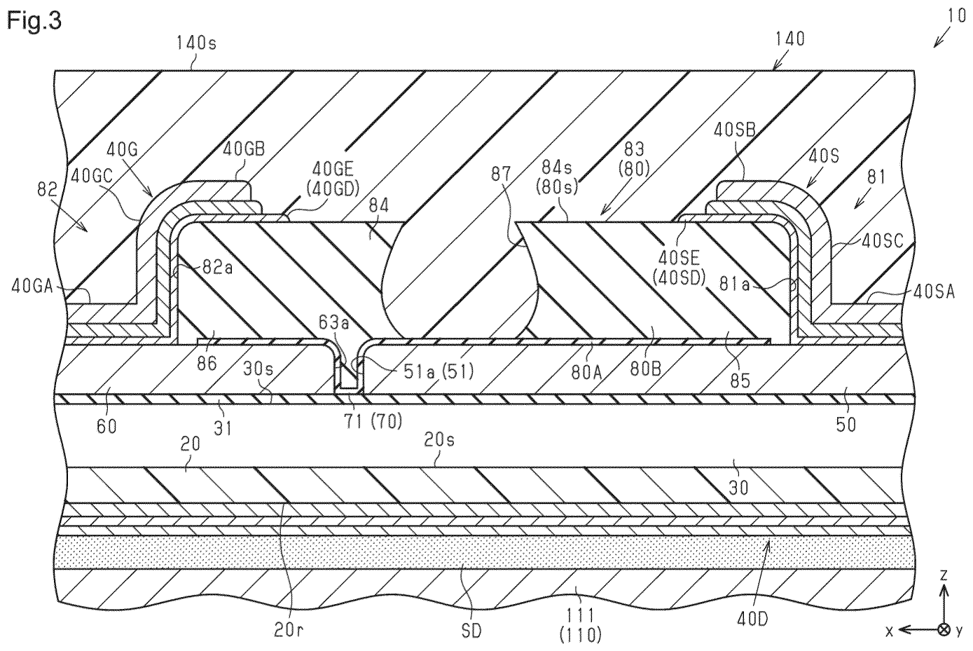

The MOSFET 10A has the shape of a rectangular flat plate. The MOSFET 10A is bonded to the first die pad portion 111 by a bonding material SD (see FIG. 3). As the bonding material, a conductive bonding material such as solder paste or silver (Ag) paste is used.

As shown in FIGS. 1 to 3, the semiconductor device 10 (MOSFET 10A) includes a source electrode 40S, a gate electrode 40G, and a drain electrode 40D. The source electrode 40S and the gate electrode 40G are formed on the front surface of the MOSFET 10A. The front surface of the MOSFET 10A faces the same side as the plastic front surface 140s. The drain electrode 40D is formed on the back surface of the MOSFET 10A. The back surface of the MOSFET 10A faces the same side as the plastic back surface. In this embodiment, the source electrode 40S corresponds to the “first electrode”, and the gate electrode 40G corresponds to the “second electrode”. In other words, the first electrode is the source electrode 40S, and the second electrode is the gate electrode 40G.

The source electrode 40S is electrically connected to the third frame 130 by a wire W1, and the gate electrode 40G is electrically connected to the second frame 120 by a wire W2. As such, the section of the second frame 120 protruding from the fourth plastic side surface 144 forms a gate terminal, and the section of the third frame 130 protruding from the fourth plastic side surface 144 forms a source terminal. The section of the first lead portion 112 that protrudes from the fourth plastic side surface 144 forms a drain terminal. These wires W1 and W2 are sealed with the sealing plastic 140.

The connection structure between the source electrode 40S and the third frame 130 may be freely modified. In one example, the source electrode 40S and the third frame 130 may be connected by a plate-shaped clip. The clip may be joined to the source electrode 40S and the third frame 130 by soldering, for example. The clip may be made of a material including copper (Cu), for example. Also, a band-shaped ribbon may be used in place of the wire W1. The connection structure between the gate electrode 40G and the second frame 120 may be freely modified. In one example, the gate electrode 40G and the second frame 120 may be connected by a plate-shaped clip. The clip may be joined to the gate electrode 40G and the second frame 120 by soldering, for example. Also, a band-shaped ribbon may be used in place of the wire W2. In short, the semiconductor device 10 may have any configuration that includes the first connection member electrically connecting the source electrode 40S and the third frame 130, and the second connection member electrically connecting the gate electrode 40G and the second frame 120. Each connection member is sealed with the sealing plastic 140.

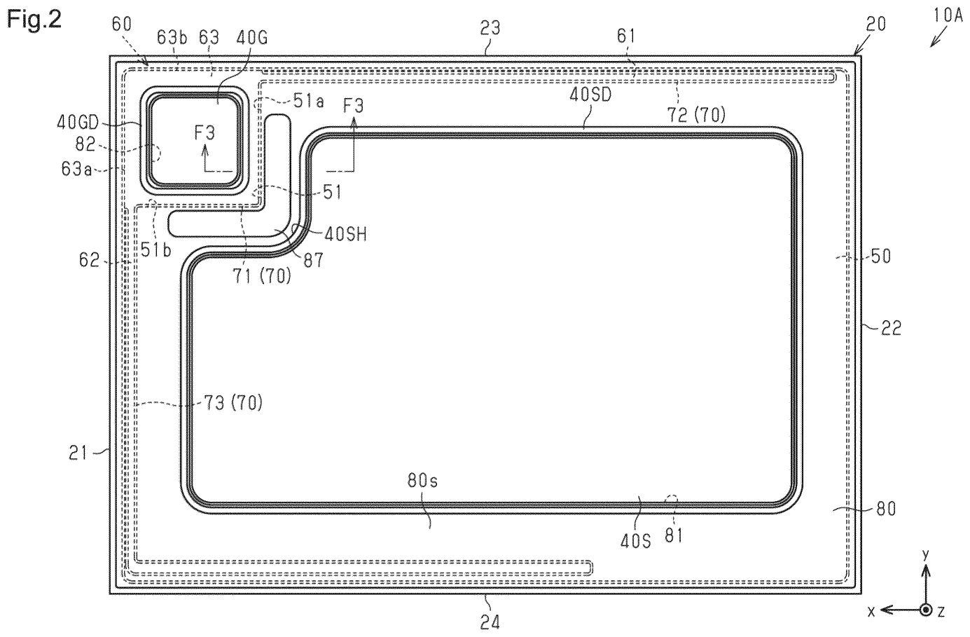

FIG. 2 shows a schematic planar structure of the MOSFET 10A, and FIG. 3 shows a schematic cross-sectional structure of the semiconductor device 10 taken along line F3-F3 in FIG. 2. FIG. 3 shows an enlarged cross-sectional structure of the MOSFET 10A between the gate electrode 40G and the source electrode 40S and the surrounding area. For illustrative purposes, the detailed configuration of a semiconductor layer 30, which will be described below, is omitted in FIG. 3.

As shown in FIG. 2, the semiconductor device 10 (MOSFET 10A) includes a semiconductor substrate 20 having the shape of a rectangular plate. The thickness direction of the semiconductor substrate 20 agrees with the z-direction. As viewed from the z-direction, the semiconductor substrate 20 is rectangular and has a longitudinal direction and a transverse direction. In this embodiment, the semiconductor substrate 20 is positioned such that its longitudinal direction agrees with the x-direction and its transverse direction agrees with the y-direction.

The semiconductor substrate 20 is made of a material including silicon (Si), for example. In this embodiment, the semiconductor substrate 20 is an Si substrate. As the semiconductor substrate 20, a silicon carbide (SiC) substrate or a gallium nitride (GaN) substrate may also be used. The semiconductor substrate 20 may have a thickness in the range of 100 μm to 700 μm, for example. In FIG. 3, for illustrative purposes, the semiconductor substrate 20 is illustrated thin.

As shown in FIG. 3, the semiconductor substrate 20 includes a substrate front surface 20s and a substrate back surface 20r facing the opposite direction from the substrate front surface 20s. The substrate front surface 20s faces the same side as the plastic front surface 140s, and the substrate back surface 20r faces the same side as the plastic back surface. As shown in FIG. 2, the semiconductor substrate 20 includes first to fourth substrate side surfaces 21 to 24. The first and second substrate side surfaces 21 and 22 form opposite end surfaces in the x-direction of the semiconductor substrate 20, and the third and fourth substrate side surfaces 23 and 24 form opposite end surfaces in the y-direction of the semiconductor substrate 20. As viewed from the z-direction, the first and second substrate side surfaces 21 and 22 both extend in the y-direction, and the third and fourth substrate side surfaces 23 and 24 both extend in the x-direction.

As shown in FIG. 3, the drain electrode 40D is formed on the substrate back surface 20r. The drain electrode 40D may be formed over the entire substrate back surface 20r, for example. The drain electrode 40D has a laminated structure of titanium, nickel, and gold (TiNiAu). More specifically, the drain electrode 40D includes a Ti layer, an Ni layer, and an Au layer. The Ti layer is in contact with the substrate back surface 20r. The Ti layer has a thickness of 0.125 μm, for example. The Ni layer is stacked on the Ti layer on the side opposite to the substrate back surface 20r. The Ni layer may be thicker than the Ti layer, for example. The Ni layer has a thickness of 0.40 μm, for example. The Au layer is stacked on the Ni layer on the opposite side to the Ti layer. The Au layer is thinner than both the Ti layer and the Ni layer, for example. The Au layer has a thickness of 0.05 μm, for example. The Au layer is in contact with the bonding material SD. The bonding material SD thus bonds the drain electrode 40D to the first die pad portion 111. The drain electrode 40D is therefore electrically connected to the first die pad portion 111. That is, the drain electrode 40D is electrically connected to the first lead portion 112 (see FIG. 1), which serves as the drain terminal.

A semiconductor layer 30 is stacked on the substrate front surface 20s. The semiconductor layer 30 is a layer formed by epitaxial growth on the semiconductor substrate 20 and is made of a material including Si, for example. The semiconductor layer 30 has a thickness in the range of 2 μm to 20 μm, for example. The thickness direction of the semiconductor layer 30 agrees with the z-direction. In this case, the expression “as viewed from the z-direction” encompasses “as viewed from the thickness direction of the semiconductor layer.” As viewed from the z-direction, the shape of the semiconductor layer 30 is rectangular, similar to the semiconductor substrate 20. Although not illustrated, the semiconductor layer 30 includes a body region, a source region, and the like as regions for forming transistors.

An oxide film 31 is formed on a front surface 30s of the semiconductor layer 30. The oxide film 31 is formed over the entire front surface 30s of the semiconductor layer 30. The oxide film 31 may be made of a material including silicon oxide (SiO₂). The oxide film 31 is formed thinner than the semiconductor layer 30. The oxide film 31 has a thickness of 0.65 μm, for example.

A source wiring line 50 and a gate wiring line 60 are formed on the oxide film 31. The source wiring line 50 and the gate wiring line 60 are therefore formed on the semiconductor layer 30. The source wiring line 50 and the gate wiring line 60 are spaced apart from each other in a direction perpendicular to the z-direction. Each of the source wiring line 50 and the gate wiring line 60 is made of a material including at least one of aluminum (Al), Cu, Ti, and the like. In this embodiment, the source wiring line 50 and the gate wiring line 60 are made of an aluminum copper alloy (AlCu). The source wiring line 50 and the gate wiring line 60 are thicker than the oxide film 31, for example. The source wiring line 50 and the gate wiring line 60 each have a thickness of 4.4 μm, for example. In this embodiment, the source wiring line 50 corresponds to the “first wiring line”, and the gate wiring line 60 corresponds to the “second wiring line”.

As shown in FIG. 2, the gate wiring line 60 is mainly formed at one of the four corners of the front surface 30s of the semiconductor layer 30 (the substrate front surface 20s of the semiconductor substrate 20 (both in FIG. 3)).

The gate wiring line 60 includes a first gate finger portion 61, a second gate finger portion 62, and a gate pad portion 63. In this embodiment, the first gate finger portion 61, the second gate finger portion 62, and the gate pad portion 63 are integral.

The gate pad portion 63 is formed in the section of the four corners of the front surface 30s of the semiconductor layer 30 (the substrate front surface 20s of the semiconductor substrate 20) near the first substrate side surface 21 and the third substrate side surface 23. The gate pad portion 63 has a rectangular shape as viewed from the z-direction. The gate pad portion 63 includes two first sides 63a and two second sides 63b. The first sides 63a form opposite end portions of the gate pad portion 63 in the x-direction. The first sides 63a extend in the y-direction. The second sides 63b form opposite end portions of the gate pad portion 63 in the y-direction. The second sides 63b extend in the x-direction.

The first gate finger portion 61 extends from the gate pad portion 63 toward the second substrate side surface 22. As viewed in the z-direction, the first gate finger portion 61 is formed so as to surround the source wiring line 50 from the side corresponding to the third substrate side surface 23.

As viewed from the z-direction, the second gate finger portion 62 is formed so as to surround the source wiring line 50 from the side corresponding to the first substrate side surface 21 and to surround a part of the source wiring line 50 from the side corresponding to the fourth substrate side surface 24. The second gate finger portion 62 includes a first section extending from the gate pad portion 63 toward the fourth substrate side surface 24, and a second section extending toward the second substrate side surface 22 from the end of the first section closer to the fourth substrate side surface 24. The first section surrounds the source wiring line 50 from the side corresponding to the first substrate side surface 21, and the second section surrounds a part of the source wiring line 50 from the side corresponding to the fourth substrate side surface 24.

The shape of the gate wiring line 60 may be freely modified. In one example, the first gate finger portion 61 and the second gate finger portion 62 may be configured to be connected to each other so as to surround the source wiring line 50. Also, at least one of the first gate finger portion 61 and the second gate finger portion 62 may be omitted.

The source wiring line 50 is formed over a major part of the front surface 30s of the semiconductor layer 30 (the substrate front surface 20s of the semiconductor substrate 20). As viewed from the z-direction, a rectangular cutout section 51 is formed in the source wiring line 50 in a section near the first and third substrate side surfaces 21 and 23.

The cutout section 51 is formed so as to be separated from the gate pad portion 63 of the gate wiring line 60. The cutout section 51 opens toward both the first and third substrate side surfaces 21 and 23. In other words, the cutout section 51 opens toward the gate pad portion 63. A part of the gate pad portion 63 is accommodated in the cutout section 51.

The cutout section 51 includes a first side 51a and a second side 51b. The first side 51a extends in the y-direction from one of the opposite end portions of the source wiring line 50 in the y-direction that is closer to the third substrate side surface 23. The second side 51b extends in the x-direction from one of the opposite end portions of the source wiring line 50 in the x-direction that is closer to the first substrate side surface 21.

In this embodiment, the region between the source wiring line 50 and the gate wiring line 60 is defined as an inter-wiring line region 70. The inter-wiring line region 70 includes a first region 71, a second region 72, and a third region 73.

The first region 71 is a region between the first and second sides 51a and 51b of the cutout section 51 of the source wiring line 50 and the first and second sides 63a and 63b of the gate pad portion 63 of the gate wiring line 60, the first and second sides 63a and 63b being opposed to the cutout section 51. The first region 71 is L-shaped as viewed from the z-direction. The region of the first region 71 extending in the y-direction is defined by the first side 51a of the cutout section 51 and the first side 63a of the gate pad portion 63. The region of the first region 71 extending in the x-direction is defined by the second side 51b of the cutout section 51 and the second side 63b of the gate pad portion 63.

The second region 72 includes a region between the first gate finger portion 61 of the gate wiring line 60 and one of the opposite end portions of the source wiring line 50 in the y-direction that is closer to the third substrate side surface 23. The second region 72 is formed around the first gate finger portion 61. Thus, the first gate finger portion 61 is surrounded by the source wiring line 50.

The third region 73 includes a region between the second gate finger portion 62 and one of the opposite end portions of the source wiring line 50 in the x-direction that is closer to the first substrate side surface 21, and includes a region between the second gate finger portion 62 and one of the opposite end portions of the source wiring line 50 in the y-direction that is closer to the fourth substrate side surface 24. The third region 73 is formed around the second gate finger portion 62. Thus, the second gate finger portion 62 is surrounded by the source wiring line 50.

The semiconductor device 10 (MOSFET 10A) includes an insulating layer 80, which covers the source wiring line 50, the gate wiring line 60, and the inter-wiring line region 70. As shown in FIG. 3, the insulating layer 80 includes a first insulating film 80A and a second insulating film 80B formed on the first insulating film 80A.

The first insulating film 80A is formed on the source wiring line 50 and the gate wiring line 60. More specifically, the first insulating film 80A is in contact with both the source wiring line 50 and the gate wiring line 60. The first insulating film 80A is also in contact with the inter-wiring line region 70. The first insulating film 80A is made of a material including silicon nitride (SiN). The thickness of the first insulating film 80A is thinner than the source wiring line 50 and the gate wiring line 60, for example. The first insulating film 80A has a thickness of 0.1 μm, for example.

The second insulating film 80B is in contact with the first insulating film 80A. The second insulating film 80B is made of an organic insulating film. In this embodiment, the second insulating film 80B is made of a material including polyimide (PI). More specifically, the second insulating film 80B is made of a material including non-photosensitive polyimide, for example. The second insulating film 80B has a greater moisture content than the first insulating film 80A. In other words, the first insulating film 80A has a lower moisture content than the second insulating film 80B. For example, when the first insulating film 80A has a lower water absorption rate than the second insulating film 80B, the first insulating film 80A has a lower moisture content than the second insulating film 80B.

The second insulating film 80B is thicker than the first insulating film 80A. The second insulating film 80B may be more than twice as thick as the first insulating film 80A. The second insulating film 80B may be more than three times as thick as the first insulating film 80A. The second insulating film 80B may be more than five times as thick as the first insulating film 80A. The second insulating film 80B may be more than ten times as thick as the first insulating film 80A. The second insulating film 80B may be more than 20 times as thick as the first insulating film 80A. The second insulating film 80B may be more than 50 times as thick as the first insulating film 80A. The second insulating film 80B may be thinner than 80 times the thickness of the first insulating film 80A. The second insulating film 80B has a thickness in the range of 4 μm to 10 μm. For example, the second insulating film 80B is thicker than the source wiring line 50 and the gate wiring line 60. In this embodiment, the second insulating film 80B has a thickness of 7 μm.

As shown in FIG. 2, the insulating layer 80 includes a first opening 81, which opens a part of the source wiring line 50, and a second opening 82, which opens a part of the gate wiring line 60. Each of the openings 81 and 82 extend through both the first and second insulating films 80A and 80B in the z-direction.

In this embodiment, the shape of the first opening 81 as viewed from the z-direction is substantially similar to the shape of the source wiring line 50 as viewed from the z-direction. As viewed from the z-direction, the first opening 81 has a smaller size than the source wiring line 50, for example. The second opening 82 is spaced apart from the first opening 81. The second opening 82 has a rectangular shape as viewed from the z-direction.

The source electrode 40S is formed to extend over the source wiring line 50, exposed through the first opening 81, and the insulating layer 80. More specifically, as shown in FIG. 3, the source electrode 40S includes a first section 40SA, which is formed on the source wiring line 50 exposed through the first opening 81, and a second section 40SB, which is formed on the insulating layer 80. The first section 40SA is in contact with the source wiring line 50 exposed through the first opening 81. The second section 40SB is in contact with the second insulating film 80B. The second section 40SB is formed at the periphery of the first opening 81. The second section 40SB surrounds the first opening 81 as viewed from the z-direction. The source electrode 40S includes a first connection section 40SC formed on a first side surface 81a defining the first opening 81. The first connection section 40SC connects the first section 40SA and the second section 40SB.

As shown in FIG. 2, the second opening 82 is formed at a position overlapping the gate pad portion 63 of the gate wiring line 60 as viewed from the z-direction. The second opening 82 exposes a part of the gate pad portion 63 through the insulating layer 80. The gate electrode 40G is formed to extend over the gate wiring line 60, exposed through the second opening 82, and the insulating layer 80. More specifically, as shown in FIG. 3, the gate electrode 40G includes a first section 40GA, which is formed on the gate wiring line 60 exposed through the second opening 82, and a second section 40GB, which is formed on the insulating layer 80. The first section 40GA is in contact with the gate wiring line 60 exposed through the second opening 82. The second section 40GB is in contact with the second insulating film 80B. As viewed from the z-direction, the second section 40GB surrounds the second opening 82. The gate electrode 40G includes a second connection section 40GC formed on a second side surface 82a defining the second opening 82. The second connection section 40GC connects the first section 40GA and the second section 40GB.

As shown in FIG. 2, the gate electrode 40G is formed at one of the four corners of the semiconductor layer 30. In this embodiment, the gate electrode 40G is formed at one of the four corners of the semiconductor layer 30 that is close to both the first and third substrate side surfaces 21 and 23. The gate electrode 40G has a rectangular shape as viewed from the z-direction.

Referring to FIG. 3, the source electrode 40S and the gate electrode 40G are made of a material including silver (Ag). More specifically, the source electrode 40S includes a laminated structure of Ti, Ni, and Ag.

The source electrode 40S includes a Ti layer, a Ni layer, and a Ag layer. The Ti layer is formed on the source wiring line 50 exposed through the first opening 81. The Ti layer is thicker than the Ti layer of the drain electrode 40D. The Ti layer of the source electrode 40S has a thickness of 0.26 μm, for example. The Ni layer is placed on the side of the Ti layer opposite from the source wiring line 50. The Ni layer may be thicker than the Ti layer, for example. The Ni layer is thinner than the Ni layer of the drain electrode 40D. The Ni layer of the source electrode 40S has a thickness of 0.30 μm, for example. The Ag layer is placed on the side of the Ni layer opposite from the Ti layer. The Ag layer may be thicker than the Ti layer, for example. The Ag layer may be thicker than the Ni layer, for example. In this embodiment, the Ag layer is thicker than both the Ti layer and the Ni layer. The Ag layer may be thicker than the Au layer of the drain electrode 40D, for example. The Ag layer has a thickness of 1 μm, for example. In the source electrode 40S, the Ni layer is formed so as to protrude beyond the Ag layer as viewed from the z-direction. The Ti layer is formed so as to protrude beyond the Ni layer. In other words, at the outer periphery of the source electrode 40S, the Ag layer is located inward of the Ti layer and the Ni layer. In a similar manner as the source electrode 40S, the gate electrode 40G includes a laminated structure of Ti, Ni, and Ag, and the thicknesses of the Ti layer, Ni layer, and Ag layer are also the same as those of the source electrode 40S.

Configuration of Section between Source Electrode and Gate Electrode

As shown in FIG. 3, the second section 40SB of the source electrode 40S includes a first edge 40SD. In other words, the first edge 40SD is formed on the upper surface 80s of the insulating layer 80. The first edge 40SD forms the outer periphery of the second section 40SB as viewed from the z-direction. Thus, as viewed from the z-direction, the first edge 40SD has the shape of a rectangle that is partly cut out.

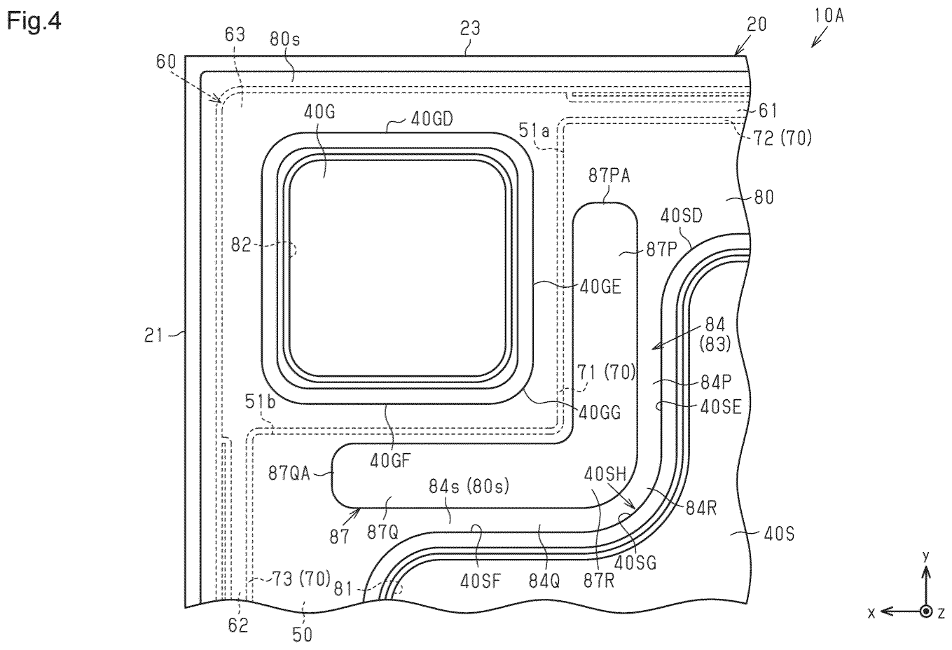

As shown in FIG. 4, the section of the first edge 40SD near the gate electrode 40G includes a first side 40SE and a second side 40SF, which are opposed to the gate electrode 40G, and a curved portion 40SG, which is provided between the first and second sides 40SE and 40SF. The first side 40SE, the second side 40SF, and the curved portion 40SG are formed so as to surround the cutout section 51. The first side 40SE extends parallel to the first side 51a of the cutout section 51. The second side 40SF extends parallel to the second side 51b of the cutout section 51. The curved portion 40SG connects the first side 40SE to the second side 40SF and is formed in a curved shape that bulges in a direction away from the gate electrode 40G as viewed from the z-direction. In this manner, the source electrode 40S includes a cutout section 40SH corresponding to the cutout section 51.

The gate electrode 40G is arranged so as to be partially accommodated in the section defined by the cutout section 40SH of the source electrode 40S. As such, the cutout section 40SH is recessed in a rectangular shape so as to be separated from the gate electrode 40G.

The second section 40GB of the gate electrode 40G includes a second edge 40GD. In other words, the second edge 40GD is formed on the upper surface 80s of the insulating layer 80. The second edge 40GD forms the outer periphery of the second section 40GB as viewed from the z-direction. As shown in FIG. 4, the second edge 40GD includes a first side 40GE, which is opposed to the first side 40SE of the first edge 40SD of the source electrode 40S, a second side 40GF, which is opposed to the second side 40SF of the first edge 40SD, and a curved portion 40GG, which is provided between the first and second sides 40GE and 40GF. The first side 40GE is one of the sides forming opposite ends in the x-direction of the gate electrode 40G that is closer to the source electrode 40S. The second side 40GF is one of the sides forming opposite ends in the y-direction of the gate electrode 40G that is closer to the source electrode 40S. As viewed from the z-direction, the first side 40GE extends in the y-direction, and the second side 40GF extends in the x-direction. That is, as viewed from the z-direction, the second side 40GF extends in a direction intersecting the first side 40GE. In this embodiment, the second side 40GF extends in a direction perpendicular to the first side 40GE as viewed from the z-direction. The curved portion 40GG is a section that connects the first side 40GE to the second side 40GF, and is formed in a curved shape that bulges toward the curved portion 40SG of the source electrode 40S. The cutout section 40SH of the source electrode 40S thus opens toward both the first side 40GE and the second side 40GF of the gate electrode 40G. The first side 40GE includes a section that extends beyond the first side 40SE of the first edge 40SD of the source electrode 40S toward the third substrate side surface 23. The second side 40GF includes a section that extends beyond the second side 40SF of the first edge 40SD of the source electrode 40S toward the first substrate side surface 21.

As shown in FIG. 3, the insulating layer 80 includes a middle portion 83 provided between the first and second openings 81 and 82. The middle portion 83 is L-shaped as viewed from the z-direction. The middle portion 83 is a section of the insulating layer 80 at which the first opening 81 and the second opening 82 are opposed to each other in the x-direction or the y-direction. In other words, the middle portion 83 is a section between the first connection section 40SC of the source electrode 40S and the second connection section 40GC of the gate electrode 40G. More specifically, the middle portion 83 is a section of the insulating layer 80 at which the first connection section 40SC and the second connection section 40GC are opposed to each other in the x-direction or the y-direction.

The middle portion 83 can be divided into an interposed portion 84, a first middle portion 85, and a second middle portion 86.

The first middle portion 85 is a section of the middle portion 83 that is closer to the first opening 81. The first middle portion 85 forms the first side surface 81a of the first opening 81. The source electrode 40S covers the upper surface of the first middle portion 85. In other words, the first middle portion 85 is a section that overlaps the second section 40SB of the source electrode 40S as viewed from the z-direction. The first edge 40SD of the source electrode 40S is thus formed on the upper surface of the first middle portion 85. More specifically, the first and second sides 40SE and 40SF of the first edge 40SD of the source electrode 40S are formed on the upper surface of the first middle portion 85.

The second middle portion 86 is a section of the middle portion 83 that is closer to the second opening 82 and forms the second side surface 82a of the second opening 82. The gate electrode 40G covers the upper surface of the second middle portion 86. In other words, the second middle portion 86 is a section that overlaps the second section 40GB of the gate electrode 40G as viewed from the z-direction. The second edge 40GD of the gate electrode 40G is thus formed on the upper surface of the second middle portion 86. More specifically, a part of the first side 40GE and a part of the second side 40GF of the second edge 40GD of the gate electrode 40G are formed on the upper surface of the second middle portion 86. The second middle portion 86 does not include the section that overlaps in the z-direction the section of the first side 40GE of the second edge 40GD of the gate electrode 40G that extends beyond the first side 40SE of the first edge 40SD of the source electrode 40S toward the third substrate side surface 23 (see FIG. 4). Also, the second middle portion 86 does not include the section that overlaps in the z-direction the section of the second side 40GF of the second edge 40GD of the gate electrode 40G that extends beyond the second side 40SF of the first edge 40SD of the source electrode 40S toward the first substrate side surface 21 (see FIG. 4).

The interposed portion 84 is a section between the first and second middle portions 85 and 86. In other words, the interposed portion 84 is a section between the first edge 40SD of the source electrode 40S and the second edge 40GD of the gate electrode 40G. The source electrode 40S and the gate electrode 40G are not formed on the upper surface 84s of the interposed portion 84. In other words, the interposed portion 84 is a section of the middle portion 83 that does not overlap the source electrode 40S or the gate electrode 40G as viewed from the z-direction. The upper surface 84s of the interposed portion 84 is in contact with the sealing plastic 140. The sealing plastic 140 covers the source electrode 40S, the gate electrode 40G, and the insulating layer 80.

The interposed portion 84 covers the first region 71. In other words, the first region 71 is formed at a position different from the source electrode 40S and the gate electrode 40G as viewed from the z-direction. The first region 71 is formed between the source electrode 40S and the gate electrode 40G. The section of the interposed portion 84 that covers the first region 71 is thicker than the other section of the interposed portion 84.

As shown in FIG. 4, the interposed portion 84 is L-shaped as viewed from the z-direction. More specifically, the interposed portion 84 can be divided into a first section 84P, which extends in the y-direction, a second section 84Q, which extends in the x-direction, and a bent portion 84R, which is provided between the first and second sections 84P and 84Q.

The first section 84P is a section between the first edge 40SD of the source electrode 40S and the second edge 40GD of the gate electrode 40G in the x-direction. The section of the first section 84P between the first side 40SE of the first edge 40SD and the first side 40GE of the second edge 40GD has a uniform width. The width of the first section 84P is the dimension in a direction (x-direction) perpendicular to the direction in which the first section 84P extends (y-direction) as viewed from the z-direction. The section of the first section 84P between the first side 40SE of the first edge 40SD and the first side 40GE of the second edge 40GD thus has a uniform width when the difference between the maximum and minimum values of the width of the section of the first section 84P between the first side 40SE and the first side 40GE is within 20% of the maximum value of the section of the first section 84P between the first side 40SE and the first side 40GE. The section of the first section 84P between the first side 40SE and the first side 40GE has a smaller width than the section that is closer to the third substrate side surface 23 than this section.

The second section 84Q is a section between the first edge 40SD of the source electrode 40S and the second edge 40GD of the gate electrode 40G in the y-direction. The section of the second section 84Q between the second side 40SF of the first edge 40SD and the second side 40GF of the second edge 40GD has a uniform width. The width of the second section 84Q is the dimension in a direction (y-direction) perpendicular to the direction in which the second section 84Q extends (x-direction) as viewed from the z-direction. The section of the second section 84Q between the second side 40SF of the first edge 40SD and the second side 40GF of the second edge 40GD thus has a uniform width when the difference between the maximum and minimum values of the width of the section of the second section 84Q between the second side 40SF and the second side 40GF is within 20% of the maximum value of the section of the second section 84Q between the second side 40SF and the second side 40GF. The section of the second section 84Q between the second side 40SF and the second side 40GF has a smaller width than the section that is closer to the first substrate side surface 21 than this section.

In this embodiment, the width of the section of the first section 84P between the first side 40SE of the first edge 40SD and the first side 40GE of the second edge 40GD is equal to the width of the section of the second section 84Q between the second side 40SF of the first edge 40SD and the second side 40GF of the second edge 40GD.

The bent portion 84R is a section that connects the first section 84P to the second section 84Q and is located between the curved portion 40SG of the first edge 40SD of the source electrode 40S and the curved portion 40GG of the second edge 40GD of the gate electrode 40G.

The interposed portion 84 includes a groove 87 recessed toward the semiconductor layer 30 from the upper surface 84s of the interposed portion 84. The groove 87 extends along at least one of the first edge 40SD of the source electrode 40S and the second edge 40GD of the gate electrode 40G. The groove 87 is L-shaped as viewed from the z-direction. The groove 87 includes a first extension portion 87P, which is formed in the first section 84P of the interposed portion 84, a second extension portion 87Q, which is formed in the second section 84Q, and a bent portion 87R, which is formed in the bent portion 84R. The first extension portion 87P, the second extension portion 87Q, and the bent portion 87R are connected. The bent portion 84R connects the first extension portion 87P to the second extension portion 87Q.

The first extension portion 87P extends in the y-direction. The first extension portion 87P extends along the first side 40GE of the second edge 40GD of the gate electrode 40G. The end portion 87PA of the opposite end portions in the y-direction of the first extension portion 87P that is closer to the third substrate side surface 23 is formed at a position closer to the third substrate side surface 23 than the first edge 40SD of the source electrode 40S. That is, the length in the y-direction of the first extension portion 87P is greater than the length in the y-direction of the first side 40SE of the first edge 40SD of the source electrode 40S. The first extension portion 87P is thus formed along the entire length of the first section 84P of the interposed portion 84. That is, the first extension portion 87P is formed along the entire length of the first section 84P in the y-direction, which is the direction in which the first section 84P extends. The end portion 87PA includes curved portions at opposite ends in the x-direction.

The second extension portion 87Q extends in the x-direction. The second extension portion 87Q extends along the second side 40GF of the second edge 40GD of the gate electrode 40G. The end portion 87QA of the opposite end portions in the x-direction of the second extension portion 87Q that is closer to the first substrate side surface 21 is formed at a position closer to the first substrate side surface 21 than the first edge 40SD of the source electrode 40S. That is, the length in the x-direction of the second extension portion 87Q is greater than the length in the x-direction of the second side 40SF of the first edge 40SD of the source electrode 40S. The end portion 87QA includes curved portions at opposite ends in the y-direction.

The shapes of the end portions 87PA and 87QA may be freely modified. In one example, the entire end portion 87PA may be formed in a curved shape as viewed from the z-direction. Also, the entire end portion 87QA may be formed in a curved shape as viewed from the z-direction.

The bent portion 87R is formed in a curved shape that bulges toward the curved portion 40SG of the first edge 40SD of the source electrode 40S. As such, in this embodiment, the groove 87 extends along the entire length of the interposed portion 84 as viewed from the z-direction.

The groove 87 is formed at a position different from the first region 71 as viewed from the z-direction. In this embodiment, the groove 87 is formed at a position closer to the source electrode 40S than the first region 71. The groove 87 is thus formed at a position overlapping the source wiring line 50 as viewed from the z-direction. In this embodiment, the groove 87 is formed at a position closer to the first region 71 than the source electrode 40S. The distance between the first extension portion 87P and the first region 71 in the x-direction is equal to the distance between the second extension portion 87Q and the first region 71 in the y-direction. In one example, these distances are about 20 μm.

As viewed from the z-direction, the groove 87 has a uniform width. The groove 87 thus has a uniform width when the difference between the maximum and minimum values of the width of the groove 87 is within 20% of the width of the groove 87 as viewed from the z-direction. The width of the groove 87 is the dimension of the groove 87 in a direction perpendicular to the direction in which the groove 87 extends as viewed from the z-direction. For example, the width of the first extension portion 87P of the groove 87 is the dimension in a direction (x-direction) perpendicular to the direction in which the first extension portion 87P extends (y-direction) as viewed from the z-direction. The width of the second extension portion 87Q of the groove 87 is the dimension in a direction (y-direction) perpendicular to the direction in which the second extension portion 87Q extends (x-direction) as viewed from the z-direction. The width of the groove 87 is greater than the width of the first region 71 (the inter-wiring line region 70). The width of the first region 71 (inter-wiring line region 70) is the dimension of the first region 71 (inter-wiring line region 70) in a direction perpendicular to the direction in which the first region 71 (inter-wiring line region 70) extends as viewed from the z-direction. The width of the groove 87 is greater than the above distance. The width of the groove 87 is about 60 μm in the present embodiment.

As shown in FIG. 3, the groove 87 extends through the second insulating film 80B. However, the groove 87 does not extend through the first insulating film 80A. The first insulating film 80A forms the bottom surface of the groove 87. In one example, the groove 87 may be formed as follows. First, the second insulating film is applied to the first insulating film 80A, and then a resist is applied to the second insulating film. Then, the groove 87 is formed in the second insulating film 80B by etching. In the etching step, the first insulating film 80A is not etched. That is, as the etchant, a solvent is used that etches a material including PI but does not etch a material including SiN. Thus, the groove 87 is formed only in the second insulating film 80B. The groove 87 exposes the first insulating film 80A through the insulating layer 80. The resist is then removed.

The cross-sectional structure of the groove 87 thus formed has a curved shape recessed toward the inside of the second insulating film 80B with respect to the end portion at the upper surface of the second insulating film 80B. In the illustrated example, the section of the groove 87 closer to the upper surface 84s of the interposed portion 84 has a curved shape that curves toward the center of the groove 87 in the width direction at locations closer to the upper surface 84s. Also, the cross-sectional structure of the groove 87 has a curved shape recessed toward the inside of the second insulating film 80B with respect to the end portion at the lower surface of the second insulating film 80B. In the illustrated example, the section of the groove 87 closer to the first insulating film 80A has a curved shape that curves toward the center of the groove 87 in the width direction at locations closer to the first insulating film 80A. The cross-sectional structure of the groove 87 is a cross-sectional structure in a direction perpendicular to the direction in which the groove 87 extends. The width direction of the groove 87 is a direction perpendicular to the direction in which the groove 87 extends as viewed from the z-direction. The lower surface of the second insulating film 80B is the surface of the second insulating film 80B that is in contact with the first insulating film 80A.

The sealing plastic 140 covers the upper surface 84s of the interposed portion 84. The groove 87 is filled with the sealing plastic 140. In the groove 87, the sealing plastic 140 is in contact with the first insulating film 80A. In this embodiment, the sealing plastic 140 has a lower moisture content than the second insulating film 80B. In other words, the sealing plastic 140 is made of a resin material that has a lower moisture content than the second insulating film 80B. The first insulating film 80A has a lower moisture content than the sealing plastic 140. In one example, the sealing plastic 140 is made of a resin material having a lower water absorption rate than the second insulating film 80B.

### Operation

### Operation of the Present Embodiment is Now Described.

In the MOSFET 10A, different voltages are applied to the source electrode 40S and the gate electrode 40G, so that a voltage is applied between the source electrode 40S and the gate electrode 40G. At this time, ion migration may occur in the source electrode 40S and the gate electrode 40G. More specifically, metal ions migrating from one of the source electrode 40S and the gate electrode 40G may move toward the other of the source electrode 40S and the gate electrode 40G via the insulating layer 80 (interposed portion 84) between the source electrode 40S and the gate electrode 40G. As a result, the source electrode 40S and the gate electrode 40G may be electrically connected to each other by metal ions. That is, the source electrode 40S and the gate electrode 40G may be short-circuited.

In general, the interposed portion 84 that is made of PI with a high moisture content facilitates the migration of metal ions. Additionally, since Ag is generally more easily ionized than Au, when the source electrode 40S and the gate electrode 40G are made of a material including Ag, ion migration is more likely to occur as compared with a configuration in which the source electrode 40S and the gate electrode 40G are made of a material including Au instead of Ag. For this reason, when the interposed portion 84 is made of PI and when the source electrode 40S and the gate electrode 40G are made of a material including Ag, the source electrode 40S and the gate electrode 40G tend to short-circuit due to ion migration.

In this regard, the interposed portion 84 of the present embodiment includes the groove 87. The groove 87 extends through the second insulating film 80B to expose the first insulating film 80A, and the groove 87 is filled with the sealing plastic 140 having a lower moisture content than the second insulating film 80B. As a result, even if metal ions migrating from the source electrode 40S and the gate electrode 40G move through the second insulating film 80B, the movement is hindered by the first insulating film 80A and the sealing plastic 140 in the groove 87. Thus, the source electrode 40S and the gate electrode 40G are less likely to be electrically connected to each other by metal ions. This limits a short circuit between the source electrode 40S and the gate electrode 40G, which would otherwise be caused by ion migration.

### Advantages

The present embodiment has the following advantages.
(1-1) The semiconductor device 10 includes the semiconductor layer 30, the source wiring line 50 and the gate wiring line 60 formed on the semiconductor layer 30 and spaced apart from each other, the insulating layer 80 that covers the source wiring line 50, the gate wiring line 60, and the inter-wiring line region 70 between the source wiring line 50 and the gate wiring line 60, and includes the first opening 81 that exposes a part of the source wiring line 50 and the second opening 82 that exposes a part of the gate wiring line 60, the source electrode 40S that is formed to extend over the source wiring line 50, exposed through the first opening 81, and the insulating layer 80 and includes the first edge 40SD located on the insulating layer 80, and the gate electrode 40G that is formed to extend over the gate wiring line 60, exposed through the second opening 82, and the insulating layer 80 and includes the second edge 40GD located on the insulating layer 80. The insulating layer 80 includes the interposed portion 84 interposed between the first edge 40SD and the second edge 40GD that are opposed to each other. The interposed portion 84 includes the groove 87 recessed toward the semiconductor layer 30 from the upper surface 84s of the interposed portion 84. The groove 87 extends along at least one of the first edge 40SD and the second edge 40GD.

In general, when a voltage is applied across the source electrode 40S and the gate electrode 40G, a short circuit may occur between the electrodes 40S and 40G due to ion migration between the electrodes 40S and 40G. In this embodiment, the groove 87 formed in the interposed portion 84 between the electrodes 40S and 40G hinders the movement of metal ions between the electrodes 40S and 40G. In other words, the ion migration is less likely to occur between the electrodes 40S and 40G. This reduces the risk of a short circuit between the source electrode 40S and the gate electrode 40G due to ion migration.
(1-2) The groove 87 extends over the entire interposed portion 84.

According to this configuration, there is a high probability that the groove 87 hinders the movement of metal ions migrating from the source electrode 40S and the gate electrode 40G. This further reduces the risk of a short circuit between the source electrode 40S and the gate electrode 40G due to ion migration.
(1-3) The interposed portion 84 covers the inter-wiring line region 70. The groove 87 is formed at a position different from the inter-wiring line region 70 as viewed from the z-direction.

According to this configuration, no step is formed in the interposed portion 84 at the position where the groove 87 is formed. In other words, the thickness of the interposed portion 84 is generally uniform. As such, the shape of the groove 87 can be formed more reliably as compared with a configuration in which the groove 87 is formed at a position overlapping the inter-wiring line region 70 as viewed from the z-direction. This reduces the possibility of the width of the groove 87 being locally narrow causing the side surfaces defining the groove 87 to be connected to each other, for example.
(1-4) At least one of the source electrode 40S and the gate electrode 40G is made of a material including Ag.

This configuration reduces costs as compared with a configuration in which at least one of the source electrode 40S and the gate electrode 40G is made of a material including Au. On the other hand, ion migration is more likely to occur in at least one of the source electrode 40S and the gate electrode 40G as compared with a configuration in which at least one of the source electrode 40S and the gate electrode 40G is made of a material including Au. In this regard, the present embodiment includes the groove 87 in the interposed portion 84, thereby limiting a short circuit between the source electrode 40S and the gate electrode 40G even if ion migration occurs. This achieves both the reduced cost of the semiconductor device 10 and the reduced risk of a short circuit between the source electrode 40S and the gate electrode 40G due to ion migration.

In particular, both the source electrode 40S and the gate electrode 40G of the present embodiment are made of a material including Ag. Consequently, ion migration tends to occur from both the source electrode 40S and the gate electrode 40G. This increases the risk of a short circuit between the source electrode 40S and the gate electrode 40G due to ion migration. However, the groove 87 of the interposed portion 84 hinders the movement of Ag ions migrating from either the source electrode 40S or the gate electrode 40G. This reduces the risk of a short circuit between the source electrode 40S and the gate electrode 40G due to ion migration.
(1-5) The source electrode 40S and the gate electrode 40G are made of the same laminated structure of a Ti layer, a Ni layer, and a Ag layer.

According to this configuration, the source electrode 40S and the gate electrode 40G can be formed in the same process, simplifying the manufacturing process of the semiconductor device 10. This reduces the manufacturing costs of the semiconductor device 10, as compared with a case in which the source electrode 40S and the gate electrode 40G have mutually different configurations.
(1-6) The insulating layer 80 includes the first insulating film 80A formed on the source wiring line 50 and the gate wiring line 60, and the second insulating film 80B formed on the first insulating film 80A. The groove 87 extends through the second insulating film 80B. The first insulating film 80A has a lower moisture content than the second insulating film 80B.

According to this configuration, the first insulating film 80A has a lower moisture content than the second insulating film 80B, so that metal ions are less likely to move in the first insulating film 80A than in the second insulating film 80B. The first insulating film 80A thus hinders the movement of metal ions migrating from the source electrode 40S and the gate electrode 40G. This reduces the risk of a short circuit between the source electrode 40S and the gate electrode 40G due to ion migration.
(1-7) The first insulating film 80A is made of a material including SiN. The second insulating film 80B is made of a material including PI.

According to this configuration, the second insulating film 80B made of a material including PI is permeable to moisture, whereas the first insulating film 80A made of a material including SiN is less permeable to moisture. As such, the first insulating film 80A limits entry of moisture into the source wiring line 50 and the gate wiring line 60. Also, the second insulating film 80B relieves the stress of the first insulating film 80A. This reduces cracking in the first insulating film 80A, thereby limiting entry of moisture into the source wiring line 50 and the gate wiring line 60 through cracks in the first insulating film 80A.
(1-8) The second insulating film 80B is thicker than the first insulating film 80A.

According to this configuration, the second insulating film 80B having a higher moisture content is likely to be softer than the first insulating film 80A having a lower moisture content. Furthermore, the second insulating film 80B that is thicker than the first insulating film 80A is more likely to reduce the stress applied to the first insulating film 80A.

On the other hand, when the second insulating film 80B with a high moisture content is thick, ion migration is likely to occur between the source electrode 40S and the gate electrode 40G. In this respect, since the second insulating film 80B of the interposed portion 84 of the present embodiment includes the groove 87, the movement of metal ions between the electrodes 40S and 40G is hindered. That is, the ion migration is less likely to occur between the electrodes 40S and 40G.
(1-9) The second insulating film 80B is made of a material including non-photosensitive polyimide. The cross-sectional structure of the groove 87 in a direction perpendicular to a direction in which the groove 87 extends includes a curved shape recessed toward the inside of the second insulating film 80B with respect to the end portion at the upper surface of the second insulating film 80B. As viewed from the z-direction, the groove 87 has a greater width than the inter-wiring line region 70.

According to this configuration, the side surfaces of the second insulating film 80B are less likely to be connected to each other at one of the end portions in the thickness direction of the second insulating film 80B, the one of the end portions being closer to the first insulating film 80A. Thus, the first insulating film 80A and the sealing plastic 140 in the groove 87 hinders the movement of metal ions migrating from the source electrode 40S and the gate electrode 40G.

### Second Embodiment

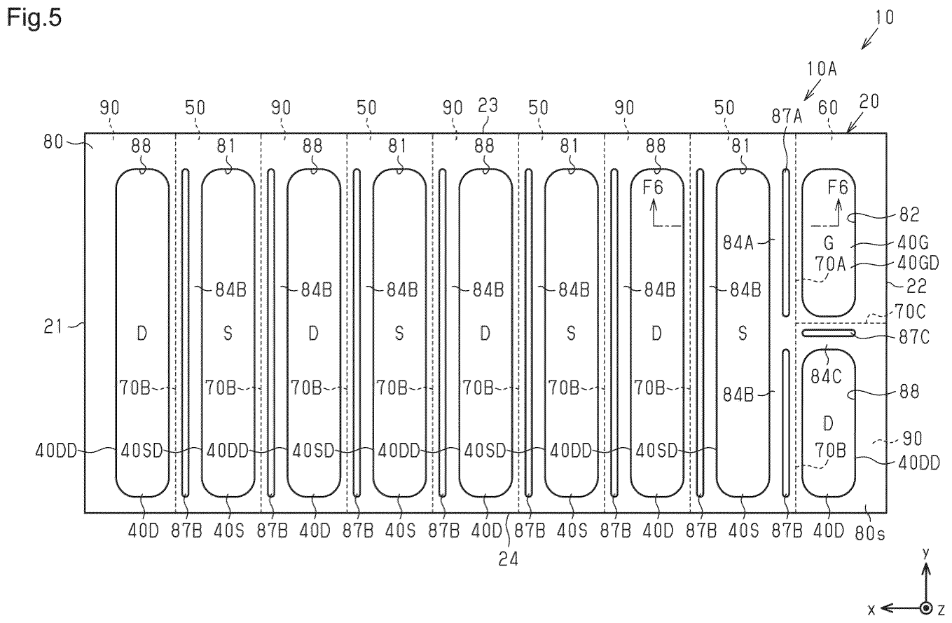

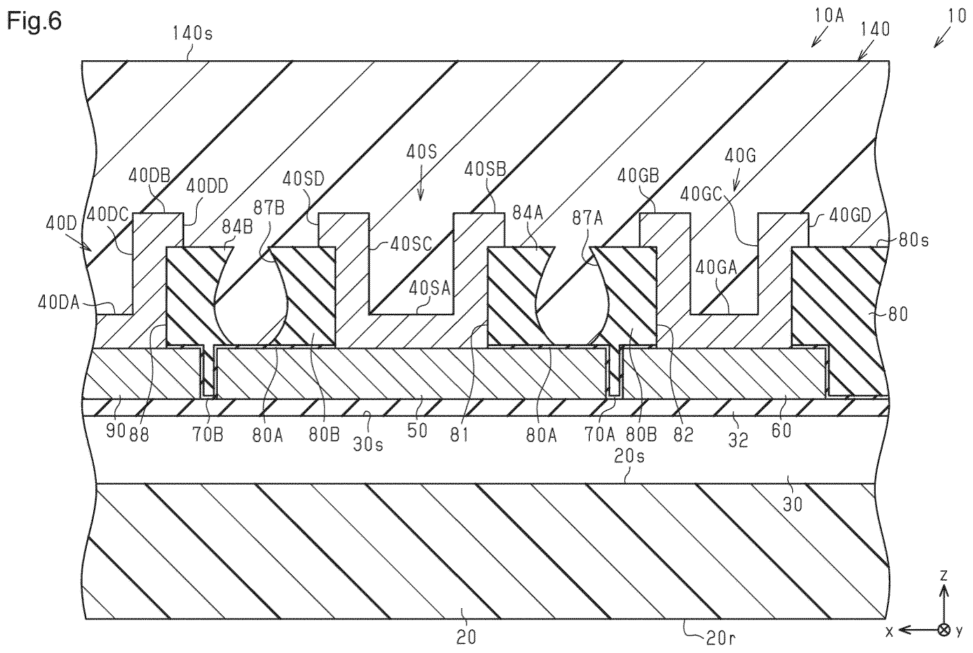

Referring to FIGS. 5 and 6, a semiconductor device 10 according to a second embodiment is now described. The second embodiment differs from the first embodiment in the arrangement of the electrodes and therefore differs in the numbers and shapes of the interposed portions and grooves. In the following description, the same reference numerals are given to the same components as in the first embodiment, and the description thereof will be omitted. In FIG. 5, first to third inter-wiring line regions 70A to 70C, which will be described below, are indicated by dashed straight lines. In FIG. 6, for illustrative purposes, a source electrode 40S, a gate electrode 40G, and a drain electrode 40D are shown in a simplified manner.

The semiconductor substrate 20 of the present embodiment is made of a material including gallium nitride (GaN). The semiconductor substrate 20 may be a GaN substrate, for example. As shown in FIG. 5, the semiconductor substrate 20 is placed such that its longitudinal direction is the x-direction and its transverse direction is the y-direction.

As shown in FIG. 6, in the same manner as the first embodiment, a semiconductor layer 30 is formed on the semiconductor substrate 20, and a passivation film 32 is formed on the semiconductor layer 30. The shape of the semiconductor layer 30 as viewed from the z-direction is rectangular, as is the semiconductor substrate 20. The structure of the GaN transistor in the semiconductor layer 30 is known, and it is omitted in FIG. 6. In one example, the GaN transistor includes a configuration in which a buffer layer, an electron transit layer, and an electron supply layer are stacked.

The semiconductor device 10 includes a source wiring line 50, a gate wiring line 60, and a drain wiring line 90 formed on the semiconductor layer 30. The source wiring line 50 and the gate wiring line 60 are spaced apart from each other. The drain wiring line 90 is spaced apart from both the source wiring line 50 and the gate wiring line 60. The source wiring line 50, the gate wiring line 60, and the drain wiring line 90 are made of AlCu, for example, as in the first embodiment. Both the source wiring line 50 and the drain wiring line 90 are electrically connected to the electron supply layer. In this embodiment, the source wiring line 50 corresponds to the “first wiring line”, the gate wiring line 60 corresponds to the “second wiring line”, and the drain wiring line 90 corresponds to the “third wiring line”.

As shown in FIG. 5, in the present embodiment, the region between the source wiring line 50 and the gate wiring line 60 is a first inter-wiring line region 70A, the region between the source wiring line 50 and the drain wiring line 90 is a second inter-wiring line region 70B, and the region between the gate wiring line 60 and the drain wiring line 90 is a third inter-wiring line region 70C. There is one first inter-wiring line region 70A, one third inter-wiring line region 70C, and multiple second inter-wiring line regions 70B (eight in this embodiment). Of the second inter-wiring line regions 70B, the second inter-wiring line region 70B closest to the second substrate side surface 22 connects to the first and third inter-wiring line regions 70A and 70C.

In this embodiment, the insulating layer 80 covers the source wiring line 50, the gate wiring line 60, the drain wiring line 90, the first inter-wiring line region 70A, the second inter-wiring line regions 70B, and the third inter-wiring line region 70C.

The insulating layer 80 includes multiple first openings 81 (four in this embodiment), one second opening 82, and multiple third openings 88 (five in this embodiment).

The first openings 81 and the third openings 88 are formed alternately in the x-direction. Of the multiple third openings 88, the third opening 88 closest to the second substrate side surface 22 has a shorter length in the y-direction than the other third openings 88. The second opening 82 is at the same position in the x-direction as one of the third openings 88 that is closest to the second substrate side surface 22, and is closer to the third substrate side surface 23 than that third opening 88. The second opening 82 has a shorter length in the y-direction than the first opening 81. As viewed from the z-direction, each of the openings 81, 82, and 88 has an elliptical shape with its transverse direction in the x-direction and its longitudinal direction in the y-direction.

The semiconductor device 10 includes multiple source electrodes 40S (four in this embodiment), one gate electrode 40G, and multiple drain electrodes 40D (five in this embodiment). In this embodiment, the source electrode 40S corresponds to the “first electrode”, the gate electrode 40G corresponds to the “second electrode”, and the drain electrode 40D corresponds to a “third electrode”. The numbers of the source electrodes 40S, the gate electrode 40G, and the drain electrodes 40D may be freely modified. In one example, the semiconductor device 10 may include one source electrode 40S. The semiconductor device 10 may include one drain electrode 40D. The semiconductor device 10 may include multiple gate electrodes 40G.

As shown in FIG. 6, each source electrode 40S is formed to extend over the source wiring line 50, exposed through the corresponding first opening 81, and the insulating layer 80. Each source electrode 40S has a first edge 40SD located on the insulating layer 80. In a similar manner as the first embodiment, each source electrode 40S includes a first section 40SA, a second section 40SB, and a first connection section 40SC.

The gate electrode 40G is formed to extend over the gate wiring line 60, exposed through the second opening 82, and the insulating layer 80. The gate electrode 40G has a second edge 40GD located on the insulating layer 80. In a similar manner as the first embodiment, the gate electrode 40G includes a first section 40GA, a second section 40GB, and a second connection section 40GC.

Each drain electrode 40D is formed spaced apart from both the source electrodes 40S and the gate electrode 40G. Each drain electrode 40D is formed to extend over the drain wiring line 90, exposed through the corresponding third opening 88, and the insulating layer 80. Each drain electrode 40D includes a third edge 40DD located on the insulating layer 80. Each drain electrode 40D includes a first section 40DA formed on the drain wiring line 90, a second section 40 DB formed on the upper surface 80s of the insulating layer 80, and a third connection section 40DC connecting the first section 40DA and the second section 40 DB. The second section 40 DB includes the third edge 40DD.

As in the first embodiment, each of the source electrodes 40S and the gate electrode 40G has a laminated structure of Ti, Ni, and Ag. Each drain electrode 40D has a similar configuration as the source electrodes 40S and the gate electrode 40G. That is, each drain electrode 40D has a laminated structure of Ti, Ni, and Ag. The drain electrodes 40D are thus made of a material including Ag.

As shown in FIG. 5, the insulating layer 80 includes a first interposed portion 84A, multiple second interposed portions 84B, and a third interposed portion 84C. The first interposed portion 84A is a section of the insulating layer 80 that is interposed between the first edge 40SD of the source electrode 40S and the second edge 40GD of the gate electrode 40G that are opposed to each other. The second interposed portion 84B is a section of the insulating layer 80 that is interposed between the first edge 40SD of the source electrode 40S and the third edge 40DD of the drain electrode 40D that are opposed to each other. The third interposed portion 84C is a section of the insulating layer 80 that is interposed between the second edge 40GD of the gate electrode 40G and the third edge 40DD of the drain electrode 40D that are opposed to each other.

The second interposed portions 84B are spaced apart from each other in the x-direction. The second interposed portions 84B extend in the y-direction. One of the second interposed portions 84B that is closest to the second substrate side surface 22 is formed at a position adjacent to the first interposed portion 84A in the y-direction.

The third interposed portion 84C is formed at a position closer to the second substrate side surface 22 than the first interposed portion 84A and the multiple second interposed portions 84B. The third interposed portion 84C extends in the x-direction. The third interposed portion 84C has a shorter length in the y-direction than the first interposed portion 84A and the second interposed portions 84B.

The first interposed portion 84A includes a first groove 87A recessed toward the semiconductor layer 30 from the upper surface of the first interposed portion 84A (the upper surface 80s of the insulating layer 80). The first groove 87A extends along at least one of the first edge 40SD of the source electrode 40S and the second edge 40GD of the gate electrode 40G. The first groove 87A extends along both the first edge 40SD and the second edge 40GD that are opposed to each other in the x-direction. The first groove 87A extends in the y-direction. The length in the y-direction of the first groove 87A is greater than or equal to the length in the y-direction of the gate electrode 40G. The first groove 87A is formed along the entire length of the first interposed portion 84A. Specifically, the first groove 87A is formed along the entire length of the first interposed portion 84A in the y-direction, which is the direction in which the first interposed portion 84A extends as viewed from the z-direction. In this embodiment, one of opposite ends in the y-direction of the first groove 87A that is closer to the third substrate side surface 23 is formed at the same position in the y-direction as one of opposite ends in the y-direction of the second edge 40GD that is closer to the third substrate side surface 23.

The first groove 87A is formed at a position different from the first inter-wiring line region 70A as viewed from the z-direction. In this embodiment, the first groove 87A is formed at a position on the opposite side of the first inter-wiring line region 70A from the gate electrode 40G in the x-direction.

Each second interposed portion 84B includes a second groove 87B recessed toward the semiconductor layer 30 from the upper surface of the second interposed portion 84B (the upper surface 80s of the insulating layer 80). The second groove 87B extends along at least one of the first edge 40SD of the source electrode 40S and the third edge 40DD of the drain electrode 40D. The second groove 87B extends along both the first edge 40SD and the third edge 40DD that are opposed to each other in the x-direction. The second groove 87B extends in the y-direction. In this embodiment, the second groove 87B is formed along the entire length of the second interposed portion 84B. Specifically, the second groove 87B is formed along the entire length of the second interposed portion 84B in the y-direction, which is the direction in which the second interposed portion 84B extends as viewed from the z-direction. More specifically, in this embodiment, the opposite ends in the y-direction of the second groove 87B are formed at the same position in the y-direction as the opposite ends in the y-direction of the first edges 40SD and the third edges 40DD. That is, the length in the y-direction of the second groove 87B is equal to the length in the y-direction of the source electrodes 40S and the drain electrodes 40D. The second groove 87B may have a greater length in the y-direction than the source electrodes 40S and the drain electrodes 40D. One of the second grooves 87B that is closest to the second substrate side surface 22 is shorter than the other second grooves 87B.

The second groove 87B is formed at a position different from the second inter-wiring line region 70B as viewed from the z-direction. In this embodiment, the second groove 87B is formed at a position closer to the source electrode 40S than the second inter-wiring line region 70B.

The third interposed portion 84C includes a third groove 87C recessed toward the semiconductor layer 30 from the upper surface of the third interposed portion 84C (the upper surface 80s of the insulating layer 80). The third groove 87C extends along at least one of the second edge 40GD of the gate electrode 40G and the third edge 40DD of the drain electrode 40D. The third groove 87C extends along both the second edge 40GD and the third edge 40DD that are opposed to each other in the y-direction. The third groove 87C extends in the x-direction. In this embodiment, the third groove 87C is formed along the entire length of the third interposed portion 84C. Specifically, the third groove 87C is formed along the entire length of the third interposed portion 84C in the x-direction, which is the direction in which the third interposed portion 84C extends as viewed from the z-direction. More specifically, in this embodiment, one of opposite ends in the x-direction of the third groove 87C that is closer to the second substrate side surface 22 is formed at the same position in the x-direction as one of opposite ends in the x-direction of each of the second edge 40GD and the third edge 40DD that is closer to the second substrate side surface 22. The third groove 87C has a greater length in the x-direction than the gate electrodes 40G and the drain electrodes 40D.

The third groove 87C is formed at a position different from the third inter-wiring line region 70C as viewed from the z-direction. In this embodiment, the third groove 87C is formed at a position closer to the drain electrode 40D than the third inter-wiring line region 70C.

As viewed from the z-direction, the widths of the grooves 87A to 87C are uniform. The first groove 87A is considered to have a uniform width when the difference between the maximum and minimum values of the width of the first groove 87A is within 20% of the width of the first groove 87A as viewed from the z-direction. The second groove 87B is considered to have a uniform width when the difference between the maximum and minimum values of the width of the second groove 87B is within 20% of the width of the second groove 87B as viewed from the z-direction. The third groove 87C is considered to have a uniform width when the difference between the maximum and minimum values of the width of the third groove 87C is within 20% of the width of the third groove 87C as viewed from the z-direction.

The first groove 87A has a greater width than the first inter-wiring line region 70A. The second groove 87B has a greater width than the second inter-wiring line region 70B. The third groove 87C has a greater width than the third inter-wiring line region 70C. The width of the first groove 87A may be defined by the dimension of the first groove 87A in the x-direction. The width of the second groove 87B may be defined by the dimension of the second groove 87B in the x-direction. The width of the third groove 87C may be defined by the dimension of the third groove 87C in the y-direction. The width of the first inter-wiring line region 70A may be defined by the dimension of the first inter-wiring line region 70A in the x-direction. The width of the second inter-wiring line region 70B may be defined by the dimension of the second inter-wiring line region 70B in the x-direction. The width of the third inter-wiring line region 70C may be defined by the dimension of the third inter-wiring line region 70C in the y-direction.

As shown in FIG. 6, the grooves 87A to 87C extend through the second insulating film 80B of the insulating layer 80, in the same manner as the first embodiment. The first insulating film 80A forms the bottom surfaces of the grooves 87A to 87C.

The sealing plastic 140 covers the source electrodes 40S, the gate electrode 40G, the drain electrodes 40D, and the interposed portions 84A to 84C. The grooves 87A to 87C are filled with the sealing plastic 140.

### Advantages

The present embodiment has the following advantages, as well as the same advantages as the first embodiment.
(2-1) The semiconductor device 10 further includes the drain wiring line 90 formed on the semiconductor layer 30 and spaced apart from both the source wiring line 50 and the gate wiring line 60, and the drain electrode 40D formed on the semiconductor layer 30 and spaced apart from both the source electrode 40S and the gate electrode 40G. The insulating layer 80 further covers the drain wiring line 90, the second inter-wiring line region 70B between the source wiring line 50 and the drain wiring line 90, and the third inter-wiring line region 70C between the gate wiring line 60 and the drain wiring line 90, and includes the third opening 88 that exposes a part of the drain wiring line 90. The drain electrode 40D is formed to extend over the drain wiring line 90, exposed through the third opening 88, and the insulating layer 80, and includes the third edge 40DD located on the insulating layer 80. The second interposed portion 84B interposed between the first edge 40SD and the third edge 40DD that are opposed to each other includes the second groove 87B recessed toward the semiconductor layer 30 from the upper surface of the second interposed portion 84B. The third interposed portion 84C interposed between the second edge 40GD and the third edge 40DD that are opposed to each other includes the third groove 87C recessed toward the semiconductor layer 30 from the upper surface of the third interposed portion 84C. The second groove 87B extends along at least one of the first edge 40SD and the third edge 40DD. The third groove 87C extends along at least one of the second edge 40GD and the third edge 40DD.

According to this configuration, the first groove 87A hinders the movement of metal ions migrating from the source electrode 40S or the gate electrode 40G. The second groove 87B hinders the movement of metal ions migrating from the source electrode 40S or the drain electrode 40D. The third groove 87C hinders the movement of metal ions migrating from the gate electrode 40G or the drain electrode 40D. This reduces the risk of a short circuit between the electrodes 40S, 40G, and 40D due to ion migration.

### Modifications

The above-described examples may be modified as follows. The examples described above and the modifications described below can be combined as long as the combined modifications remain technically consistent with each other.

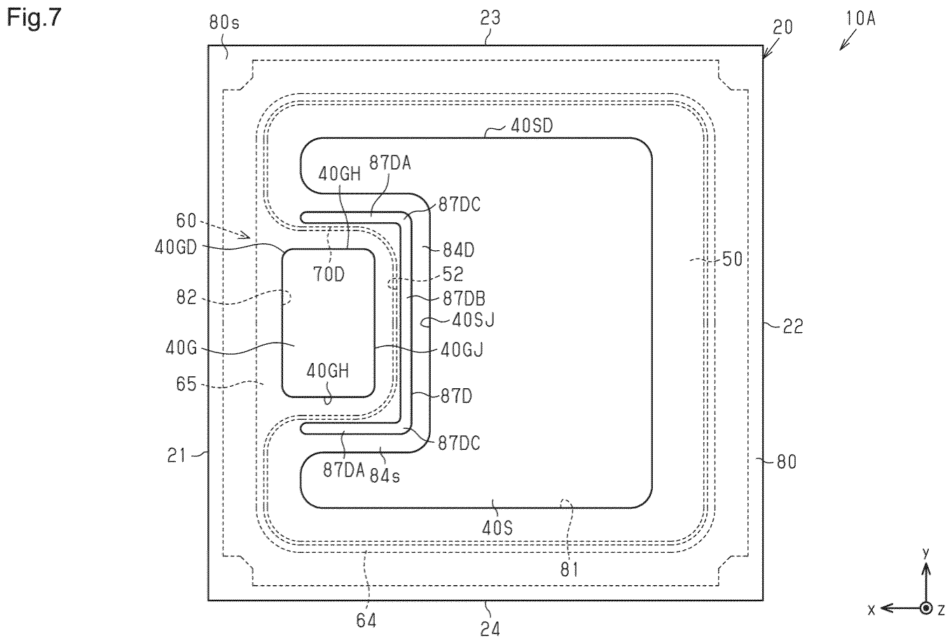

In the first embodiment, the arrangement position of the gate electrode 40G may be freely modified. For example, as shown in FIG. 7, the gate electrode 40G may be located at a position other than the four corners of the semiconductor substrate 20. More specifically, the gate electrode 40G may be located at a position closer to the first substrate side surface 21 than the center of the semiconductor substrate 20 in the x-direction and at the center of the semiconductor substrate 20 in the y-direction. In this case, the shapes of the source wiring line 50 and the gate wiring line 60 are different from those in the first embodiment.

The source wiring line 50 is formed over a major part of the semiconductor substrate 20 as viewed from the z-direction. One of opposite end portions in the x-direction of the source wiring line 50 that is closer to the first substrate side surface 21 includes a recess 52 opening toward the first substrate side surface 21.

The gate wiring line 60 includes a gate finger portion 64 and a gate pad portion 65. The gate pad portion 65 has a rectangular shape as viewed from the z-direction. The gate pad portion 65 is accommodated in the recess 52. The gate finger portion 64 is connected to the gate pad portion 65 at a section of the gate pad portion 65 that is closer to the first substrate side surface 21 than to the recess 52 of the source wiring line 50. The gate finger portion 64 is integral with the gate pad portion 65 and is formed so as to surround the source wiring line 50. As such, the inter-wiring line region 70D between the gate wiring line 60 and the source wiring line 50 is formed in a ring shape surrounding the source wiring line 50.

The insulating layer 80 includes a first opening 81 exposing a part of the source wiring line 50 at a position overlapping the source wiring line 50. The shape of the first opening 81 as viewed from the z-direction is substantially similar to the shape of the source wiring line 50 as viewed from the z-direction. In a similar manner as the first embodiment, the source electrode 40S is formed to extend over the source wiring line 50, exposed through the first opening 81, and the insulating layer 80.

The insulating layer 80 includes a second opening 82 exposing a part of the gate wiring line 60 at a position overlapping the gate pad portion 65. The second opening 82 has a rectangular shape as viewed from the z-direction. In a similar manner as the first embodiment, the gate electrode 40G is formed to extend over the gate wiring line 60, exposed through the second opening 82, and the insulating layer 80.

The second edge 40GD of the gate electrode 40G includes two first sides 40GH spaced apart from each other in the y-direction, and a second side 40GJ connecting the first sides 40GH. The first sides 40GH extend in the x-direction. The second side 40GJ extends in the y-direction.

The shape of the source electrode 40S is different from that of the first embodiment. Specifically, the source electrode 40S includes a recess 40SJ opening toward the gate electrode 40G. In the illustrated example, the recess 40SJ opens toward the first substrate side surface 21. The recess 40SJ is recessed in a rectangular shape so as to be separated from the gate electrode 40G. As viewed from the z-direction, a part of the gate electrode 40G is accommodated in the recess 40SJ. The recess 40SJ is opposed to the first sides 40GH and the second side 40GJ. The recess 40SJ opens toward the second side 40GJ.

The insulating layer 80 includes an interposed portion 84D interposed between the two first sides 40GH and the second side 40GJ of the second edge 40GD and a section of the first edge 40SD that forms the recess 40SJ. The interposed portion 84 is substantially C-shaped as viewed from the z-direction.

The interposed portion 84D includes a groove 87D recessed toward the semiconductor layer 30 (see FIG. 3) from an upper surface 84s of the interposed portion 84D. The groove 87D is substantially C-shaped as viewed from the z-direction. The groove 87D includes two first extension portions 87DA extending along the two first sides 40GH, and a second extension portion 87DB extending along the second side 40GJ. The groove 87D also includes two bent portions 87DC, which connect the first extension portions 87DA and the second extension portion 87DB. The distal end portions of the first extension portions 87DA extend to the same position in the x-direction as one of the opposite end portions in the x-direction of the source electrode 40S that is closer to the first substrate side surface 21. Thus, in the illustrated example, the groove 87D is formed along the entire length of the interposed portion 84D as viewed from the z-direction. This configuration has the same advantageous effects as the first embodiment.

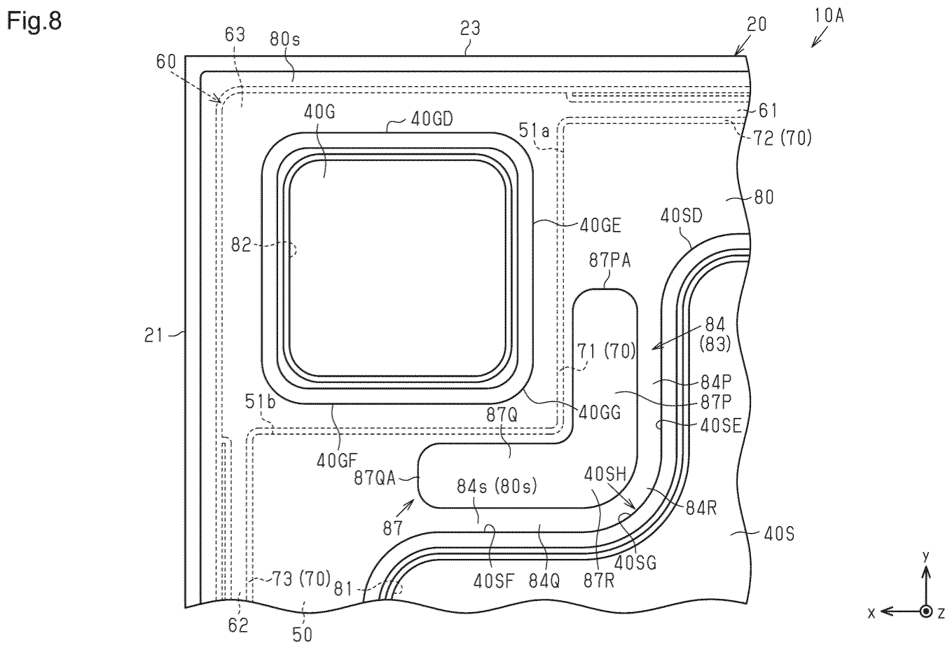

In the first embodiment, the length of the groove 87 as viewed from the z-direction may be freely modified. For example, as shown in FIG. 8, the length of the first extension portion 87P of the groove 87 may be shorter than the first extension portion 87P of the first embodiment. More specifically, the distal end portion of the first extension portion 87P and the first gate finger portion 61 may be located on opposite sides in the y-direction with respect to the section of the first edge 40SD of the source electrode 40S, the section extending along the first gate finger portion 61. The second extension portion 87Q of the groove 87 may be shorter than the second extension portion 87Q of the first embodiment. More specifically, the distal end portion of the second extension portion 87Q and the second gate finger portion 62 may be located on opposite sides in the x-direction of the section of the first edge 40SD of the source electrode 40S that extends along the second gate finger portion 62. In this manner, the groove 87 may be configured to be formed in a part of the interposed portion 84.

This configuration reduces the risk of a short circuit between the gate electrode 40G and the source electrode 40S due to ion migration between the gate electrode 40G and the source electrode 40S in the x-direction, as compared with a configuration that does not include the first extension portion 87P. The configuration also reduces the risk of a short circuit between the gate electrode 40G and the source electrode 40S due to ion migration between the gate electrode 40G and the source electrode 40S in the y-direction, as compared with a configuration that does not include the second extension portion 87Q.

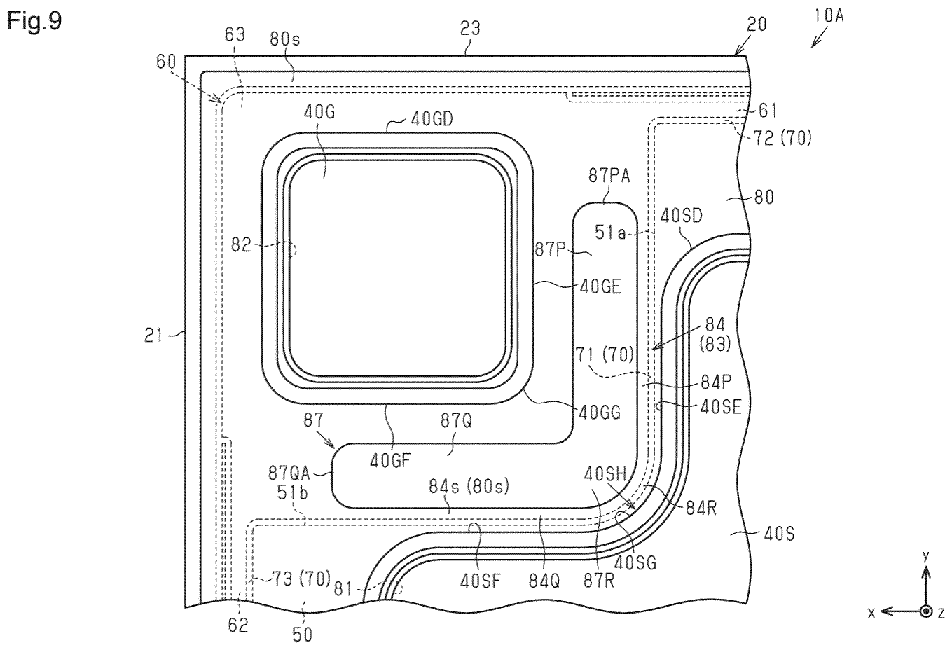

In the first embodiment, the position of the first region 71 may be freely modified. For example, as shown in FIG. 9, the first region 71 may be formed closer to the source electrode 40S than to the gate electrode 40G. In this case, the groove 87 is formed closer to the gate electrode 40G than the first region 71. That is, the groove 87 is formed at a position overlapping the gate wiring line 60 as viewed from the z-direction.

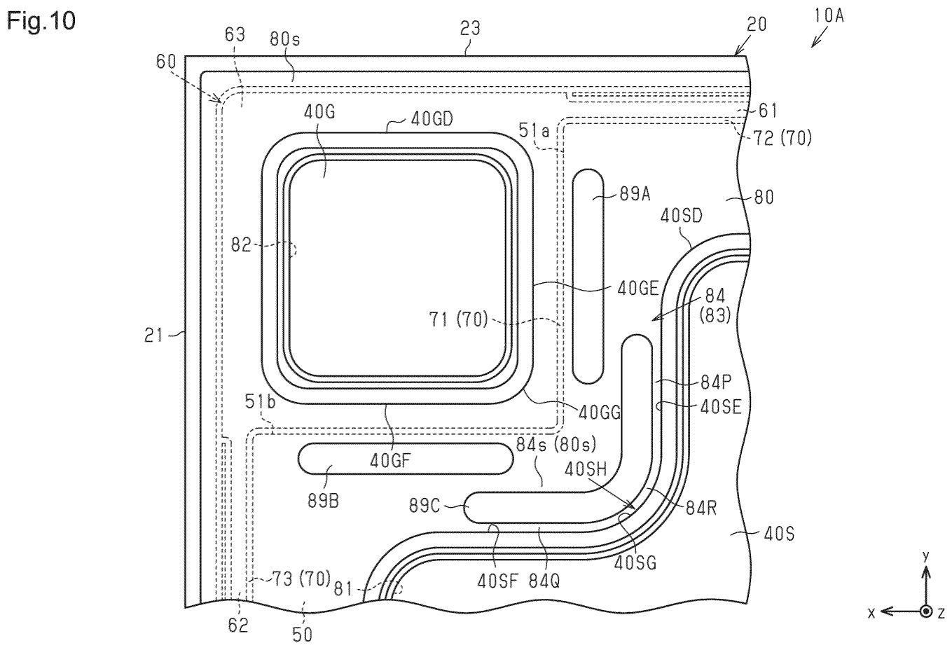

In the first embodiment, the shape of the groove 87 as viewed from the z-direction may be freely modified. For example, the shape of the groove 87 as viewed from the z-direction may be modified as in first to third modifications shown in FIGS. 10 to 12.

As shown in FIG. 10, in the first modification, the interposed portion 84 includes multiple grooves. In the illustrated example, the interposed portion 84 includes a first groove 89A, a second groove 89B, and a third groove 89C. The first groove 89A, the second groove 89B, and the third groove 89C are spaced apart from each other.

The first groove 89A is formed in the first section 84P of the interposed portion 84. The first groove 89A extends in the y-direction. The first groove 89A is formed at a position closer to the second edge 40GD of the gate electrode 40G than to the first edge 40SD of the source electrode 40S in the x-direction.

The second groove 89B is formed in the second section 84Q of the interposed portion 84. The second groove 89B extends in the x-direction. The second groove 89B is formed at a position closer to the second edge 40GD of the gate electrode 40G than to the first edge 40SD of the source electrode 40S in the y-direction.

The third groove 89C is formed in the bent portion 84R of the interposed portion 84. The third groove 89C is partially formed in both the first section 84P and the second section 84Q. The third groove 89C is L-shaped as viewed from the z-direction. The third groove 89C is formed at a position closer to the first edge 40SD of the source electrode 40S than to the second edge 40GD of the gate electrode 40G. In the illustrated example, the third groove 89C is formed so as to overlap a part of the first groove 89A as viewed from the x-direction. Also, the third groove 89C is formed so as to overlap a part of the second groove 89B as viewed from the y-direction.

The positions of the first groove 89A, the second groove 89B, and the third groove 89C may be freely modified. In one example, the first groove 89A may be formed at a position closer to the first edge 40SD of the source electrode 40S than to the second edge 40GD of the gate electrode 40G in the x-direction. The second groove 89B may be formed at a position closer to the first edge 40SD of the source electrode 40S than to the second edge 40GD of the gate electrode 40G in the y-direction. The third groove 89C may be formed at a position closer to the second edge 40GD of the gate electrode 40G than to the first edge 40SD of the source electrode 40S.

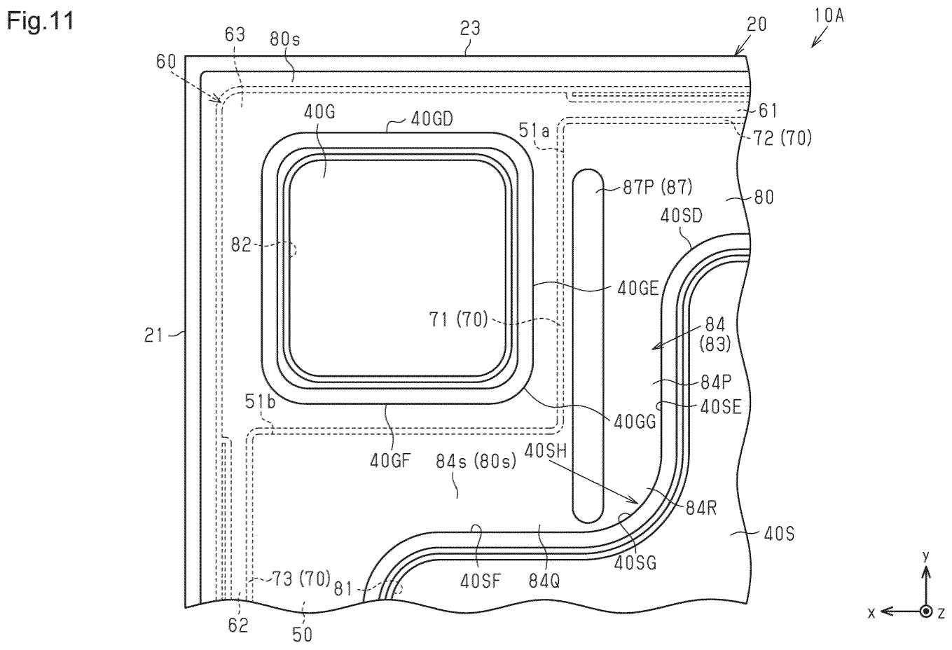

As shown in FIG. 11, in the second modification, the groove 87 extends straight in the y-direction as viewed from the z-direction. That is, the groove 87 includes a first extension portion 87P but does not include a second extension portion 87Q. The first extension portion 87P of the groove 87 extends in the y-direction. The first extension portion 87P is formed to extend beyond the second edge 40GD of the gate electrode 40G in the y-direction.

The length of the first extension portion 87P may be freely modified. In one example, the first extension portion 87P may be formed so as not to extend beyond the second edge 40GD of the gate electrode 40G in the y-direction.

In the second modification, as viewed from the z-direction, the groove 87 may be formed in the second section 84Q of the interposed portion 84, instead of the first section 84P. That is, the groove 87 may have a configuration that includes the second extension portion 87Q (see FIG. 4) but not the first extension portion 87P.

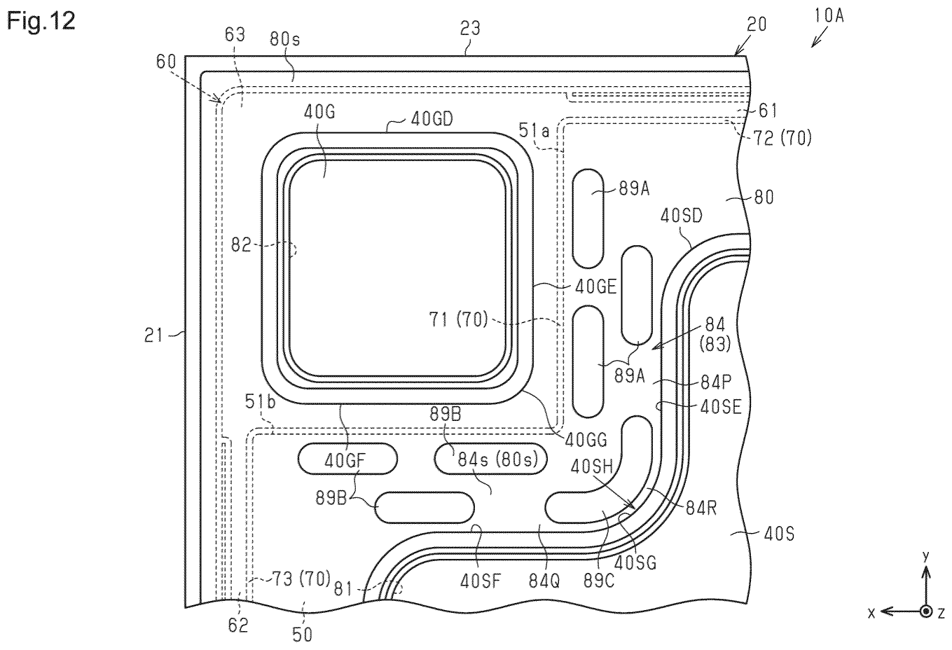

As shown in FIG. 12, in the third modification, the first section 84P and the second section 84Q of the interposed portion 84 each include multiple grooves. In the illustrated example, the first section 84P includes multiple first grooves 89A (three in FIG. 12). The second section 84Q includes multiple second grooves 89B (three in FIG. 12).

The first grooves 89A are spaced apart from one another. Some of the first grooves 89A are formed at positions offset from the other first grooves 89A in the x-direction. Some of the first grooves 89A have sections that overlap other first grooves 89A as viewed from the x-direction.

The second grooves 89B are spaced apart from one another. Some of the second grooves 89B are formed at positions offset from the other second grooves 89B in the y-direction. Some of the second grooves 89B have sections that overlap other second grooves 89B as viewed from the x-direction.

The number of the first grooves 89A and the second grooves 89B may be freely modified. Furthermore, the positions of the first grooves 89A and the second grooves 89B may be freely modified. In the third modification, multiple third grooves 89C may be formed in the bent portion 84R.

In the first embodiment, the groove 87 may be formed at a position overlapping the inter-wiring line region 70 as viewed from the z-direction.

In the embodiments, the width of each of the grooves 87 and 87A to 87C as viewed from the z-direction does not need to be uniform. For example, in the groove 87 of the first embodiment, the width dimension of the first extension portion 87P may be different from the width dimension of the second extension portion 87Q as viewed from the z-direction. The first extension portion 87P may have a greater width than the second extension portion 87Q. Also, the first extension portion 87P may have a smaller width smaller than the second extension portion 87Q.

In the second embodiment, the relationship between the widths of the first groove 87A, the second groove 87B, and the third groove 87C may be freely modified. In one example, the first groove 87A may have a greater width than the second and third grooves 87B and 87C. The second groove 87B may have a greater width than the first and second grooves 87A and 87C. The third groove 87C may have a greater width than the first and second grooves 87A and 87B.

In the first embodiment, as viewed from the z-direction, the groove 87 may have a smaller width than the inter-wiring line region 70. As viewed from the z-direction, the groove 87 may have the same width as the inter-wiring line region 70.

In the second embodiment, the first groove 87A may have a smaller width than the first inter-wiring line region 70A as viewed from the z-direction. As viewed from the z-direction, the first groove 87A may have the same width as the first inter-wiring line region 70A. As viewed from the z-direction, the second groove 87B may have a smaller width than the second inter-wiring line region 70B. As viewed from the z-direction, the second groove 87B may have the same width as the second inter-wiring line region 70B. As viewed from the z-direction, the third groove 87C may have a smaller width than the third inter-wiring line region 70C. As viewed from the z-direction, the third groove 87C may have the same width as the third inter-wiring line region 70C.

In the first embodiment, the cross-sectional shape of the groove 87 along a plane extending in the z-direction and the width direction of the groove 87 may be freely modified. For example, the cross-sectional shape of the groove 87 of a plane extending in the z-direction and the width direction of the groove 87 may be rectangular. The cross-sectional shapes of the first groove 87A, the second groove 87B, and the third groove 87C in the second embodiment may be modified in a similar manner.

In the second embodiment, the length of each of the first groove 87A, the second grooves 87B, and the third groove 87C may be freely modified. The first groove 87A may have a shorter length in the y-direction than the gate electrode 40G. The second groove 87B may have a shorter length in the y-direction than the source electrode 40S. The third groove 87C may have a shorter length in the x-direction than the gate electrode 40G or the drain electrode 40D.

Furthermore, the numbers of the first groove 87A, the second grooves 87B, and the third groove 87C may be freely modified. In one example, multiple first grooves 87A having a shorter length in the y-direction than the gate electrode 40G may be arranged, spaced apart from each other in the y-direction. Multiple second grooves 87B having a shorter length in the y-direction than the source electrode 40S may be arranged, spaced apart from each other in the y-direction. Multiple third grooves 87C having a shorter length in the x-direction than the gate electrode 40G and the drain electrode 40D may be arranged, spaced apart from each other in the x-direction.

In the second embodiment, one or two of the first groove 87A, the second grooves 87B, and the third groove 87C may be omitted.

In the first embodiment, the width of the interposed portion 84 does not need to be uniform. In one example, the first section 84P may have a greater width than the second section 84Q. In this case, the groove 87 does not need to have the first extension portion 87P. In one example, the width of the second section 84Q may be greater than the width of the first section 84P. In this case, the groove 87 does not need to have the second extension portion 87Q.

In the second embodiment, the widths of the first interposed portion 84A, the second interposed portions 84B, and the third interposed portion 84C may be different from one another. In one example, when the first interposed portion 84A has a greater width than both the second and third interposed portions 84B and 84C, the first groove 87A may be omitted. When the second interposed portion 84B has a greater width than both the first and third interposed portions 84A and 84C, the second groove 87B may be omitted. When the third interposed portion 84C has a greater width than both the first and second interposed portions 84A and 84B, the third groove 87C may be omitted.

In the first embodiment, one of the source electrode 40S and the gate electrode 40G may be made of a material that does not include Ag. In other words, any one of the source electrode 40S and the gate electrode 40G may be made of a material including Ag. In this manner, it is sufficient that at least one of the source electrode 40S and the gate electrode 40G is made of a material including Ag. In the first embodiment, both the source electrode 40S and the gate electrode 40G may be made of a material that does not include Ag.

In the second embodiment, any one or two of the drain electrodes 40D, the source electrodes 40S, and the gate electrode 40G may be made of a material that does not include Ag. In other words, any one of the drain electrodes 40D, the source electrodes 40S, and the gate electrode 40G may be made of a material including Ag. In this manner, it is sufficient that at least one of the drain electrodes 40D, the source electrodes 40S, and the gate electrode 40G is made of a material including Ag. In the second embodiment, the drain electrodes 40D, the source electrodes 40S, and the gate electrode 40G may all be made of a material that does not include Ag.

In the first embodiment, at least one of the source electrode 40S and the gate electrode 40G may be made of a material including Cu. In the first embodiment, at least one of the source electrode 40S and the gate electrode 40G may be made of a material including Cu instead of Ag.

In the second embodiment, at least one of the drain electrodes 40D, the source electrodes 40S, and the gate electrode 40G may be made of a material including Cu. In the second embodiment, at least one of the drain electrodes 40D, the source electrodes 40S, and the gate electrode 40G may be made of a material including Cu instead of Ag.

In each embodiment, the second insulating film 80B may be made of photosensitive polyimide.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily need to be the vertical direction and does not necessarily need to fully conform to the vertical direction. In the structures according to the present disclosure, “upward” and “downward” in the z-direction as referred to in the present description are not limited to “upward” and “downward” in the vertical direction. In one example, the x-direction may conform to the vertical direction. In another example, the y-direction may conform to the vertical direction.

In this specification, “at least one of A and B” should be understood to mean “only A, only B, or both A and B.”

### CLAUSES

The technical aspects that are understood from the embodiments and the modifications will be described below. To facilitate understanding without intention to limit, the reference signs of the elements in the descriptions are given to the corresponding elements in the clause with parentheses. The reference signs used as examples to facilitate understanding, and the elements in each clause are not limited to those elements given with the reference signs.
Clause 1
A semiconductor device (10), including:
a semiconductor layer (30);
a first wiring line (50) and a second wiring line (60) that are formed on the semiconductor layer (30) and spaced apart from each other;
an insulating layer (80) that covers the first wiring line (50), the second wiring line (60), and an inter-wiring line region (70) between the first wiring line (50) and the second wiring line (60), and includes a first opening (81) that exposes a part of the first wiring line (50) and a second opening (82) that exposes a part of the second wiring line (60);
a first electrode (40S) that is formed to extend over the first wiring line (50) and the insulating layer (80), the first wiring line (50) being exposed through the first opening (81), the first electrode (40S) including a first edge (40SD) located on the insulating layer (80); and
a second electrode (40G) that is formed to extend over the second wiring line (60) and the insulating layer (80), the second wiring line (60) being exposed through the second opening (82), the second electrode (40G) including a second edge (40GD) located on the insulating layer (80), in which
the insulating layer (80) includes an interposed portion (84) interposed between the first edge (40SD) and the second edge (40GD) that are opposed to each other,
the interposed portion (84) includes a groove (87) that is recessed toward the semiconductor layer (30) from an upper surface (84s) of the interposed portion (84), and
the groove (87) extends along at least one of the first edge (40SD) and the second edge (40GD).
Clause 2
The semiconductor device according to clause 1, in which the groove (87) extends over the entire interposed portion (84).
Clause 3
The semiconductor device according to clause 1 or 2, in which
the interposed portion (84) covers the inter-wiring line region (70), and
the groove (87) is formed at a position different from the inter-wiring line region (70) as viewed from a thickness direction (z-direction) of the semiconductor layer (30).
Clause 4
The semiconductor device according to any one of clauses 1 to 3, in which, as viewed from a thickness direction (z-direction) of the semiconductor layer (30), the groove (87) has a greater width than the inter-wiring line region (70).
Clause 5
The semiconductor device according to any one of clauses 1 to 4, in which
the semiconductor device (10) includes a MOSFET,
the first electrode is a source electrode (40S), and
the second electrode is a gate electrode (40G).
Clause 6
The semiconductor device according to clause 5, in which
the semiconductor layer (30) has a rectangular shape as viewed from a thickness direction (z-direction) of the semiconductor layer (30),
the second electrode (40G) is formed at one of four corners of the semiconductor layer (30) and has a rectangular shape as viewed from the thickness direction (z-direction) of the semiconductor layer (30),
the second edge (40GD) of the second electrode (40G) includes a first side (40GE) and a second side (40GF) that intersects with the first side (40GE),
the first electrode (40S) includes a cutout section (40SH) that is opposed to the first side (40GE) and the second side (40GF), opens toward both the first side (40GE) and the second side (40GF), and is recessed in a rectangular shape so as to be separated from the second electrode (40S), and
the groove (87) includes a first extension portion (87P) extending along the first side (40GE) and a second extension portion (87Q) extending along the second side (40GF).
Clause 7
The semiconductor device according to clause 5, in which
the semiconductor layer (30) has a rectangular shape as viewed from a thickness direction (z-direction) of the semiconductor layer (30),
the second electrode (40G) has a rectangular shape as viewed from the thickness direction (z-direction) of the semiconductor layer (30),
the second edge (40GD) of the second electrode (40G) includes two first sides (40GH) spaced apart from each other in a direction perpendicular to the thickness direction (z-direction) of the semiconductor layer (30), and a second side (40GJ) connecting the two first sides (40GH),
the first electrode (40S) includes a recess (40SJ) that is opposed to the two first sides (40GH) and the second side (40GJ), opens toward the second side (40GJ), and is recessed in a rectangular shape so as to be separated from the second electrode (40G), and
the groove (87) includes two first extension portions (87DA) extending along the two first sides (40GH) and a second extension portion (87 DB) extending along the second side (40GJ).
Clause 8
The semiconductor device according to any one of clauses 1 to 4, further including:
a third wiring line (90) that is formed on the semiconductor layer (30) and spaced apart from both the first wiring line (50) and the second wiring line (60); and
a third electrode (40D) spaced apart from both the first electrode (40S) and the second electrode (40G), in which
the insulating layer (80) further covers the third wiring line (90), a second inter-wiring line region (70B) between the first wiring line (50) and the third wiring line (90), and a third inter-wiring line region (70C) between the second wiring line (60) and the third wiring line (90), and includes a third opening (88) that exposes a part of the third wiring line (90),
the third electrode (40D) is formed to extend over the third wiring line (90) and the insulating layer (80), the third wiring line (90) being exposed through the third opening (88), the third electrode (40D) including a third edge (40DD) located on the insulating layer (80),
a second interposed portion (84B), interposed between the first edge (40SD) and the third edge (40DD) that are opposed to each other, includes a second groove (87B) recessed toward the semiconductor layer (30) from an upper surface of the second interposed portion (84B),
a third interposed portion (84C), interposed between the second edge (40GD) and the third edge (40DD) that are opposed to each other, includes a third groove (87C) recessed toward the semiconductor layer (30) from an upper surface of the third interposed portion (84C),
the second groove (87B) extends along at least one of the first edge (40SD) and the third edge (40DD), and
the third groove (87C) extends along at least one of the second edge (40GD) and the third edge (40DD).
Clause 9
The semiconductor device according to any one of clauses 1 to 8, in which at least one of the first electrode (40S) and the second electrode (40G) is made of a material including Ag.
Clause 10
The semiconductor device according to any one of clauses 1 to 9, in which
the first electrode (40S) includes:
   a section (40SA) formed on the first wiring line (50);
   a section (40SB) formed on an upper surface of the insulating layer (80); and
   a first connection section (40SC) that is formed on a first side surface (81a) defining the first opening (81), and that connects the section (40SA) formed on the first wiring line (50) and the section (40SB) formed on the upper surface of the insulating layer (80), and
the second electrode (40G) includes:
   a section (40GA) formed on the second wiring line (60);
   a section (40GB) formed on an upper surface of the insulating layer (80); and
   a second connection section (40GC) that is formed on a second side surface (82a) defining the second opening (82), and that connects the section (40GA) formed on the second wiring line (60) and the section (40GB) formed on the upper surface of the insulating layer (80).
Clause 11
The semiconductor device according to any one of clauses 1 to 10, in which
the insulating layer (80) includes:
   a first insulating film (80A) formed on the first wiring line (50) and the second wiring line (60); and
   a second insulating film (80B) formed on the first insulating film (80A), and
the groove (87) extends through the second insulating film (80B).
Clause 12
The semiconductor device according to clause 11, in which the first insulating film (80A) has a lower moisture content than the second insulating film (80B).
Clause 13
The semiconductor device according to clause 12, further including
a sealing plastic (140) covering the first electrode (40S), the second electrode (40G), and the insulating layer (80), in which
the groove (87) is filled with the sealing plastic (140), and
the sealing plastic (140) has a lower moisture content than the second insulating film (80B).
Clause 14
The semiconductor device according to any one of clauses 11 to 13, in which
the first insulating film (80A) is made of a material including silicon nitride, and
the second insulating film (80B) is made of a material including polyimide.
Clause 15
The semiconductor device according to any one of clauses 11 to 14, in which the second insulating film (80B) is thicker than the first insulating film (80A).
Clause 16
The semiconductor device according to any one of clauses 11 to 15, in which
the second insulating film (80B) is made of a material including non-photosensitive polyimide, and
a cross-sectional structure of the groove (87) in a direction perpendicular to a direction in which the groove (87) extends has a curved shape recessed toward an inside of the second insulating film (80B) with respect to an end portion at an upper surface of the second insulating film (80B).
Clause 17
The semiconductor device according to any one of clauses 1 to 16, in which the groove (87) is one of multiple grooves spaced apart from each other.

The above description is merely exemplary. One skilled in the art may recognize further possible combinations and replacements of the elements and methods (manufacturing processes) in addition to those listed for purposes of describing the techniques of the present disclosure. The present disclosure is intended to cover all alternatives, variations, and modifications falling within the scope of this disclosure, including the claims and clauses.

### REFERENCE SIGNS LIST

10) Semiconductor Device
10A) MOSFET
20) Semiconductor Substrate
20s) Substrate Front Surface
20r) Substrate Back Surface
21) First Substrate Side Surface
22) Second Substrate Side Surface
23) Third Substrate Side Surface
24) Fourth Substrate Side Surface
30) Semiconductor Layer
30s) Front Surface
31) Oxide Film
32) Passivation Film
40D) Drain Electrode (Third Electrode)
40DA) First Section
40 DB) Second Section
40DC) Third Connection Section
40DD) Third Edge
40S) Source Electrode (First Electrode)
40SA) First Section
40SB) Second Section
40SC) First Connection Section
40SD) First Edge
40SE) First Side
40SF) Second Side
40SG) Curved Portion
40SH) Cutout Section
40SJ) Recess
40G) Gate Electrode (Second Electrode)
40GA) First Section
40GB) Second Section
40GC) Second Connection Section
40GD) Second Edge
40GE) First Side
40GF) Second Side
40GG) Curved Portion
40GH) First Side
40GJ) Second Side
50) Source Wiring Line (First Wiring Line)
51) Cutout Section
51a) First Side
51b) Second Side
52) Recess
60) Gate Wiring Line (Second Wiring Line)
61) First Gate Finger Portion
62) Second Gate Finger Portion
63) Gate Pad Portion
63a) First Side
63b) Second Side
64) Gate Finger Portion
65) Gate Pad Portion
70) Inter-Wiring Line Region
70A) First Inter-Wiring Line Region
70B) Second Inter-Wiring Line Region
70C) Third Inter-Wiring Line Region
70D) Inter-Wiring Line Region
71) First Region
72) Second Region
73) Third Region
80) Insulating Layer
80A) First Insulating Film
80B) Second Insulating Film
80s) Upper Surface
81) First Opening
81a) First Side Surface
82) Second Opening
82a) Second Side Surface
83) Middle Portion
84) Interposed Portion
84A) First Interposed Portion
84B) Second Interposed Portion
84C) Third Interposed Portion
84D) Interposed Portion
84s) Upper Surface
84P) First Section
84Q) Second Section
84R) Bent Portion
85) First Middle Portion
86) Second Middle Portion
87) Groove
87A) First Groove
87B) Second Groove
87C) Third Groove
87D) Groove
87DA) First Extension Portion
87 DB) Second Extension Portion
87DC) Bent Portion
87P) First Extension Portion
87PA) End Portion
87Q) Second Extension Portion
87QA) End Portion
87R) Bent Portion
88) Third Opening
89A) First Groove
89B) Second Groove
89C) Third Groove
90) Drain Wiring Line (Third Wiring Line)
110) First Frame
111) First Die Pad Portion
112) First Lead Portion
120) Second Frame
130) Third Frame
140) Sealing Plastic
140s) Plastic Front Surface
141) First Plastic Side Surface
142) Second Plastic Side Surface
143) Third Plastic Side Surface
144) Fourth Plastic Side Surface
W1, W2) Wire
SD) Bonding Material

1. A semiconductor device, comprising:
a semiconductor layer;
a first wiring line and a second wiring line that are formed on the semiconductor layer and spaced apart from each other;
an insulating layer that covers the first wiring line, the second wiring line, and an inter-wiring line region between the first wiring line and the second wiring line, and includes a first opening that exposes a part of the first wiring line and a second opening that exposes a part of the second wiring line;
a first electrode that is formed to extend over the first wiring line and the insulating layer, the first wiring line being exposed through the first opening, the first electrode including a first edge located on the insulating layer; and
a second electrode that is formed to extend over the second wiring line and the insulating layer, the second wiring line being exposed through the second opening, the second electrode including a second edge located on the insulating layer, wherein
the insulating layer includes an interposed portion interposed between the first edge and the second edge that are opposed to each other,
the interposed portion includes a groove that is recessed toward the semiconductor layer from an upper surface of the interposed portion, and
the groove extends along at least one of the first edge and the second edge.

2. The semiconductor device according to claim 1, wherein the groove extends over the entire interposed portion.

3. The semiconductor device according to claim 1, wherein
the interposed portion covers the inter-wiring line region, and
the groove is formed at a position different from the inter-wiring line region as viewed from a thickness direction of the semiconductor layer.

4. The semiconductor device according to claim 1, wherein, as viewed from a thickness direction of the semiconductor layer, the groove has a greater width than the inter-wiring line region.

5. The semiconductor device according to claim 1, wherein
the semiconductor device includes a MOSFET,
the first electrode is a source electrode, and
the second electrode is a gate electrode.

6. The semiconductor device according to claim 5, wherein
the semiconductor layer has a rectangular shape as viewed from a thickness direction of the semiconductor layer,
the second electrode is formed at one of four corners of the semiconductor layer and has a rectangular shape as viewed from the thickness direction of the semiconductor layer,
the second edge of the second electrode includes a first side and a second side that intersects with the first side,
the first electrode includes a cutout section that is opposed to the first side and the second side, opens toward both the first side and the second side, and is recessed in a rectangular shape so as to be separated from the second electrode, and
the groove includes a first extension portion extending along the first side and a second extension portion extending along the second side.

7. The semiconductor device according to claim 5, wherein
the semiconductor layer has a rectangular shape as viewed from a thickness direction of the semiconductor layer,
the second electrode has a rectangular shape as viewed from the thickness direction of the semiconductor layer,
the second edge of the second electrode includes two first sides spaced apart from each other in a direction perpendicular to the thickness direction of the semiconductor layer, and a second side connecting the two first sides,
the first electrode includes a recess that is opposed to the two first sides and the second side, opens toward the second side, and is recessed in a rectangular shape so as to be separated from the second electrode, and
the groove includes two first extension portions extending along the two first sides and a second extension portion extending along the second side.

8. The semiconductor device according to claim 1, further comprising:
a third wiring line that is formed on the semiconductor layer and spaced apart from both the first wiring line and the second wiring line; and
a third electrode spaced apart from both the first electrode and the second electrode, wherein
the insulating layer further covers the third wiring line, a second inter-wiring line region between the first wiring line and the third wiring line, and a third inter-wiring line region between the second wiring line and the third wiring line, and includes a third opening that exposes a part of the third wiring line,
the third electrode is formed to extend over the third wiring line and the insulating layer, the third wiring line being exposed through the third opening, the third electrode including a third edge located on the insulating layer,
a second interposed portion, interposed between the first edge and the third edge that are opposed to each other, includes a second groove recessed toward the semiconductor layer from an upper surface of the second interposed portion,
a third interposed portion, interposed between the second edge and the third edge that are opposed to each other, includes a third groove recessed toward the semiconductor layer from an upper surface of the third interposed portion,
the second groove extends along at least one of the first edge and the third edge, and
the third groove extends along at least one of the second edge and the third edge.

9. The semiconductor device according to claim 1, wherein at least one of the first electrode and the second electrode is made of a material including Ag.

10. The semiconductor device according to claim 1, wherein
the first electrode includes:
a section formed on the first wiring line;
a section formed on an upper surface of the insulating layer; and
a first connection section that is formed on a first side surface defining the first opening, and that connects the section formed on the first wiring line and the section formed on the upper surface of the insulating layer, and
the second electrode includes:
a section formed on the second wiring line;
a section formed on an upper surface of the insulating layer; and
a second connection section that is formed on a second side surface defining the second opening, and that connects the section formed on the second wiring line and the section formed on the upper surface of the insulating layer.

11. The semiconductor device according to claim 1, wherein
the insulating layer includes:
a first insulating film formed on the first wiring line and the second wiring line; and
a second insulating film formed on the first insulating film, and
the groove extends through the second insulating film.

12. The semiconductor device according to claim 11, wherein the first insulating film has a lower moisture content than the second insulating film.

13. The semiconductor device according to claim 12, further comprising:
a sealing plastic covering the first electrode, the second electrode, and the insulating layer, wherein
the groove is filled with the sealing plastic, and
the sealing plastic has a lower moisture content than the second insulating film.

14. The semiconductor device according to claim 11, wherein
the first insulating film is made of a material including silicon nitride, and
the second insulating film is made of a material including polyimide.

15. The semiconductor device according to claim 11, wherein the second insulating film is thicker than the first insulating film.

16. The semiconductor device according to claim 11, wherein
the second insulating film is made of a material including non-photosensitive polyimide, and
a cross-sectional structure of the groove in a direction perpendicular to a direction wherein the groove extends has a curved shape recessed toward an inside of the second insulating film with respect to an end portion at a lower surface of the second insulating film.
